(19) United States
(12) Patent Application Publication
(10) Pub. No.: US 2026/0360434 A1
(43) Pub. Date: Nov. 12, 2026

(54) MEMORY DEVICE AND PROGRAM OPERATION THEREOF

(71) Applicant: Yangtze Memory Technologies Co., Ltd., Wuhan (CN)

(72) Inventors: Weijun WAN, Wuhan (CN); Yue Sheng, Wuhan (CN); Wei Huang, Wuhan (CN); Chunyuan Hou, Wuhan (CN)

(21) Appl. No.: 19/236,874

(22) Filed: Jun. 12, 2025

Related U.S. Application Data
(63) Continuation of application No. PCT/CN2025/093297, filed on May 8, 2025.

(51) Int. Cl. G11C 16/10; G11C 16/04; G11C 16/08; G11C 16/24

(52) U.S. Cl. CPC G11C 16/102; G11C 16/0433; G11C 16/08; G11C 16/24

(57) ABSTRACT

In certain aspects, a method for operating a memory device is provided. The memory device includes memory strings each including a DSG transistor and memory cells. In a first period of a program operation, an on voltage is applied to a first DSG line coupled to the DSG transistor of a first memory string of the memory strings, and an off voltage is applied to a second DSG line coupled to the DSG transistor of a second memory string of the memory strings. In a second period of the program operation after the first period, an on voltage is applied to the second DSG line coupled to the DSG transistor of the second memory string, and an off voltage is applied to the first DSG line coupled to the DSG transistor of the first memory string. In a third period of the program operation after the second period, the off voltages is applied to the first and second DSG lines coupled to the DSG transistors of the first and second memory strings, respectively, and a program voltage pulse is applied to a select word line, wherein the select word line is coupled to a first memory cell of the memory cells in the first memory string and a second memory cell of the memory cells in the second memory string.

### CROSS-REFERENCE TO RELATED APPLICATIONS

This application is a continuation of International Application No. PCT/CN 2025/093297, filed on May 8, 2025, which is incorporated herein by reference in its entirety. This application is also related to co-pending U.S. application Ser. No. ________, Attorney Docketing No.: 10018-01-0735-US, filed on even date, entitled “MEMORY DEVICE AND PROGRAM OPERATION THEREOF,” and co-pending U.S. application Ser. No. ________, Attorney Docketing No.: 10018-01-0737-US, filed on even date, entitled “MEMORY DEVICE AND PROGRAM OPERATION THEREOF,” both of which are incorporated herein by reference in their entireties.

### BACKGROUND

The present disclosure relates to memory devices and operation methods thereof.

Flash memory is a low-cost, high-density, non-volatile solid-state storage medium that can be electrically erased and reprogrammed. Flash memory includes NOR Flash memory and NAND Flash memory. Various operations can be performed by Flash memory, such as read, program (write), and erase. For NAND Flash memory, an erase operation can be performed at the block level, and a program operation or a read operation can be performed at the page level.

### SUMMARY

In one aspect, a memory device includes memory strings each including a drain select gate (DSG) transistor and memory cells, word lines and DSG lines coupled to the memory strings, and a peripheral circuit coupled to the memory strings through the word lines and the DSG lines. The peripheral circuit is configured to, in a program operation, program a first memory cell of the memory cells in a first memory string of the memory strings, and a second memory cell of the memory cells in a second memory string of the memory strings. The first memory cell and the second memory cell are coupled to a same select word line of the word lines. The peripheral circuit includes a word line driver configured to in in a first period of the program operation, apply an on voltage to a first DSG line of the DSG lines coupled to the DSG transistor of the first memory string, and apply an off voltage to a second DSG line coupled to a second DSG line of the DSG lines coupled to the DSG transistor of the second memory string. The word line driver is also configured to in a second period of the program operation after the first period, apply an on voltage to the second DSG line coupled to the DSG transistor of the second memory string, and apply an off voltage to the first DSG line coupled to the DSG transistor of the first memory string. The word line driver is further configured to in a third period of the program operation after the second period, apply an off voltage to the first and second DSG lines coupled to the DSG transistors of the first and second memory strings, respectively, and apply a program voltage pulse to the select word line.

In some implementations, to apply the program voltage pulse to the select word line, the word line driver is configured to, in the third period, ramp up the program voltage pulse on the select word line to a first level, and maintain the program voltage pulse on the select word line at the first level.

In some implementations, the word line driver is configured to in the second period, apply a voltage at a second level lower than the first level on the select word line.

In some implementations, the word line driver is configured to in a fourth period of the program operation before the second period, ramp up the voltage on the select word line to the second level.

In some implementations, the word line driver is further configured to apply a continuous pass voltage pulse to an unselect word line of the word lines during the second and third periods of the program operation.

In some implementations, to apply the continuous pass voltage pulse to the unselect word line, the word line driver is configured to ramp up the pass voltage pulse on the unselect word line to a third level after the first period, and maintain the pass voltage pulse on the unselect word line at the third level in the second and third periods.

In some implementations, the memory device includes a bit line coupled to the first memory cell and the second memory cell, and the peripheral circuit further includes a page buffer coupled to the bit line and configured to apply a bit line voltage to the bit line during the first period and the second period.

In some implementations, the bit line voltage is at a ground level.

In some implementations, the word line driver is further configured to, in a fifth period of the program operation after the third period apply the on voltages to the first and second DSG lines coupled to the DSG transistors of the first and second memory strings, respectively, and discharge the program voltage pulse on the select word line.

In some implementations, the peripheral circuit is further configured to, in the program operation, program a third memory cell of the memory cells in a third memory string of the memory strings, the third memory cell being coupled to the select word line, and the word line driver is further configured to in a sixth period of the program operation after the second period and before the third period, apply an on voltage to a third DSG line of the DSG lines coupled to the DSG transistor of the third memory string, and apply the off voltages to the first and second DSG lines coupled to the DSG transistors of the first and second memory strings, respectively.

In some implementations, the program operation is performed for single-level cells (SLCs).

In some implementations, a channel potential of the first memory string is at a non-boosted level in the first, second, and third periods, a channel potential of the second memory string is at a non-boosted level in the second and third periods, and a channel potential of the third memory string is at a non-boosted level in the third period.

In another aspect, a method for operating a memory device is provided. The memory device includes memory strings each including a DSG transistor and memory cells. In a first period of a program operation, an on voltage is applied to a first DSG line coupled to the DSG transistor of a first memory string of the memory strings, and an off voltage is applied to a second DSG line coupled to the DSG transistor of a second memory string of the memory strings. In a second period of the program operation after the first period, an on voltage is applied to the second DSG line coupled to the DSG transistor of the second memory string, and an off voltage is applied to the first DSG line coupled to the DSG transistor of the first memory string. In a third period of the program operation after the second period, the off voltages is applied to the first and second DSG lines coupled to the DSG transistors of the first and second memory strings, respectively, and a program voltage pulse is applied to a select word line, wherein the select word line is coupled to a first memory cell of the memory cells in the first memory string and a second memory cell of the memory cells in the second memory string.

In some implementations, to apply the program voltage pulse to the select word line comprises, in the third period, the program voltage pulse is ramped up on the select word line to a first level, and the program voltage pulse is maintained on the select word line at the first level.

In some implementations, in a fourth period of the program operation before the second period, the voltage is ramped up on the select word line to the second level.

In some implementations, a continuous pass voltage pulse is applied to an unselect word line during the second and third periods of the program operation.

In some implementations, to apply the continuous pass voltage pulse to the unselect word line, the pass voltage pulse is ramped up on the unselect word line to a third level after the first period, and the pass voltage pulse is maintained on the unselect word line at the third level in the second and third periods.

In some implementations, a bit line voltage is applied to a bit line during the first period and the second period. In some implementations, the bit line is coupled to the first memory cell and the second memory cell.

In some implementations, the bit line voltage is at a ground level.

In some implementations, in a fifth period of the program operation after the third period, the on voltages are applied to the first and second DSG lines coupled to the DSG transistors of the first and second memory strings, respectively, and the program voltage pulse is discharged on the select word line.

In some implementations, in a sixth period of the program operation after the second period and before the third period, an on voltage is applied to a third DSG line coupled to the DSG transistor of a third memory string of the memory strings, and the off voltages are applied to the first and second DSG lines coupled to the DSG transistors of the first and second memory strings, respectively.

In still another aspect, a system includes a memory device configured to store data, and a memory controller coupled to the memory device and configured to control the memory device. The memory device includes memory strings each including a DSG transistor and memory cells, word lines and DSG lines coupled to the memory strings, and a peripheral circuit coupled to the memory strings through the word lines and the DSG lines. The peripheral circuit is configured to, in a program operation, program a first memory cell of the memory cells in a first memory string of the memory strings, and a second memory cell of the memory cells in a second memory string of the memory strings. The first memory cell and the second memory cell are coupled to a same select word line of the word lines. The peripheral circuit includes a word line driver configured to in in a first period of the program operation, apply an on voltage to a first DSG line of the DSG lines coupled to the DSG transistor of the first memory string, and apply an off voltage to a second DSG line coupled to a second DSG line of the DSG lines coupled to the DSG transistor of the second memory string. The word line driver is also configured to in a second period of the program operation after the first period, apply an on voltage to the second DSG line coupled to the DSG transistor of the second memory string, and apply an off voltage to the first DSG line coupled to the DSG transistor of the first memory string. The word line driver is further configured to in a third period of the program operation after the second period, apply an off voltage to the first and second DSG lines coupled to the DSG transistors of the first and second memory strings, respectively, and apply a program voltage pulse to the select word line.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a memory device including peripheral circuits, according to some aspects of the present disclosure.

FIG. 2 illustrates a side view of a cross-section of a memory cell array including a NAND memory string, according to some aspects of the present disclosure.

FIG. 3 illustrates a block diagram of a memory device including a memory cell array and peripheral circuits, according to some aspects of the present disclosure.

FIGS. 4A and 4B illustrate schematic diagrams of three-dimensional (3D) NAND memory strings, according to some aspects of the present disclosure.

FIGS. 5A and 5B illustrate a waveform of word line voltages applied to a select word line in a program operation in a single-level cell (SLC) mode, according to some aspects of the present disclosure.

FIG. 6A illustrates timing diagrams of a program operation in an SLC mode, according to some aspects of the present disclosure.

FIG. 6B illustrates timing diagrams of another program operation in an SLC mode, according to some aspects of the present disclosure.

FIG. 7 illustrates timing diagrams of still another program operation in an SLC mode, according to some aspects of the present disclosure.

FIG. 8 illustrates interface timing diagrams of a program operation in an SLC mode, according to some aspects of the present disclosure.

FIG. 9 illustrates interface timing diagrams of another program operation in an SLC mode, according to some aspects of the present disclosure.

FIG. 10 illustrates interface timing diagrams of still another program operation in an SLC mode, according to some aspects of the present disclosure.

FIG. 11 illustrates interface timing diagrams of yet another program operation in an SLC mode, according to some aspects of the present disclosure.

FIG. 12 illustrates a flowchart of a method for programming a memory device in an SLC mode, according to some aspects of the present disclosure.

FIG. 13 illustrates a flowchart of another method for programming a memory device in an SLC mode, according to some aspects of the present disclosure.

FIG. 14 illustrates a flowchart of still another method for programming a memory device in an SLC mode, according to some aspects of the present disclosure.

FIG. 15 illustrates a block diagram of a system having a memory device, according to some aspects of the present disclosure.

FIG. 16A illustrates a diagram of a memory card having a memory device, according to some aspects of the present disclosure.

FIG. 16B illustrates a diagram of a solid-state drive (SSD) having a memory device, according to some aspects of the present disclosure.

The present disclosure will be described with reference to the accompanying drawings.

### DETAILED DESCRIPTION

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Memory devices, such as NAND Flash memory devices, can be programmed in single-level cell (SLC) mode in which each memory cell is programmed into either the programmed state or the erased state (1 bit per cell). This is the simplest and most reliable form of NAND Flash programming. SLC programming (programming in the SLC mode) can be used for programming the SLC cache, which is a portion of the NAND memory reserved to run in SLC mode, for memory devices in the multi-level cell (MLC), triple-level cell (TLC), or quad-level cell (QLC)) mode, for example, in buffer incoming writes at high speed or power loss protection. SLC programming can also be used for programming boot code storage, wear leveling and overprovisioning zones, etc. Moreover, some MLC/TLC NAND chips can be programmed in SLC mode to mimic SLC behavior.

Accordingly, the speed of SLC programming (tPROG) has become an important factor that affects the overall performance of the memory devices. However, as the memory array loading keeps increasing due to the increased numbers of memory cells, the durations of the pre-pulse (e.g., boosting) and post-pulse (e.g., recovery) periods in each SLC program operation are increasing, much less can be reduced, which becomes a bottleneck for improving the overall device performance.

To address one or more of the aforementioned issues, the present disclosure provides various SLC programming schemes that apply a continuous program voltage pulse, instead of multiple program voltage pulses, to the select word line once in one program operation in the SLC mode for the select word line. In other words, the program voltage applied to the select word line no longer needs to be charged and discharged between programming different memory strings when programming via the select word line. As a result, the boosting and recovery only need to be performed once in the program operation for the select word line, thereby reducing the SLC programming time and improving the overall device performance.

According to one aspect of the present disclosure, a continuous program voltage pulse is maintained during sequentially setting up bit lines and drain select gate (DSG) transistors for each memory string coupled to the select word line. According to another aspect of the present disclosure, a program voltage pulse is applied after sequentially setting up bit lines and DSG transistors for each memory string coupled to the select word line.

Moreover, the present disclosure further provides various interface protocols that support the SLC programming schemes disclosed herein to allow consecutively loading multiple pages of data for SLC programming and programming multiple memory cells coupled to the select word line based on the multiple pages of data in the SLC mode using the disclosed SLC programming schemes. The interface protocols disclosed herein can support multi-page co-programming in either a single plane or multiple planes.

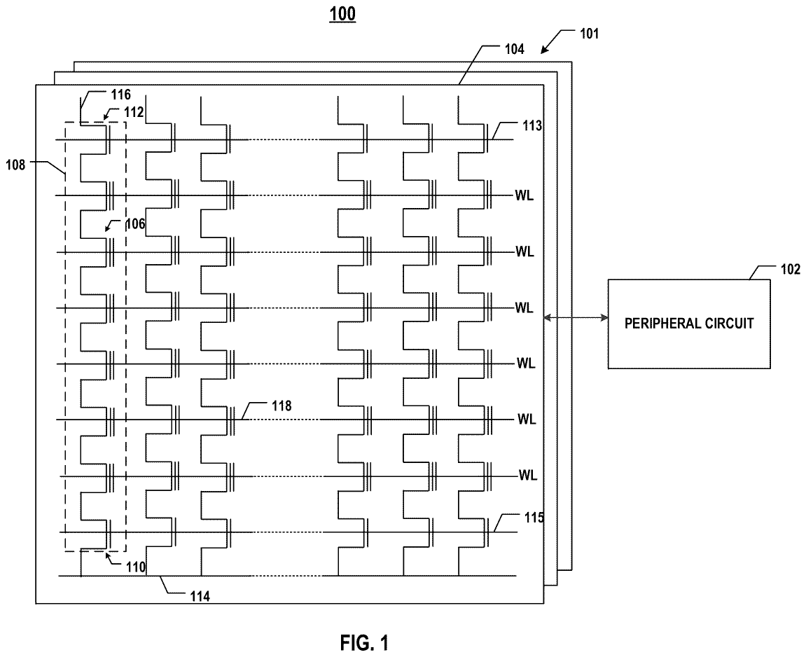

FIG. 1 illustrates a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge, which depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is an SLC that has two possible levels (memory states) and thus, can store one bit of data. For example, the first level “0 ” can correspond to a first range of threshold voltages, and the second level “1” can correspond to a second range of threshold voltages. In some implementations, each memory cell 106 is an xLC that is capable of storing more than a single bit of data in more than four levels. For example, the xLC may store two bits per cell (MLC), three bits per cell (TLC), or four bits per cell (QLC)). Each xLC can be programmed to assume a range of possible nominal storage values (i.e., corresponding to 2^{N} pieces of N-bits data). In some implementations, at least one of memory cells 106 is set to one of 2^{N} levels corresponding to a piece of N-bits data, where N is an integer greater than 1.

As shown in FIG. 1, each NAND memory string 108 can also include a source select gate (SSG) transistor 110 (a.k.a., bottom select gate (BSG) transistor) at its source end and a drain select gate (DSG) transistor 112 (a.k.a., top select gate (TSG) transistor) at its drain end. SSG transistor 110 and DSG transistor 112 can be configured to activate select NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. The drain of each NAND memory string 108 is coupled to a respective bit line 116 from which data can be read or written via an output bus (not shown), according to some implementations. In some implementations, each NAND memory string 108 is configured to be selected or deselected by applying a select voltage (e.g., a positive voltage greater than the threshold voltage of DSG transistor 112) or a deselect voltage (e.g., the ground voltage) to the gate of respective DSG transistor 112 through one or more DSG lines 113 and/or by applying a select voltage (e.g., a positive voltage greater than the threshold voltage of SSG transistor 110) or a deselect voltage (e.g., the ground voltage) to the gate of respective SSG transistor 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a select block 104, source lines 114 coupled to select block 104 as well as unselect blocks 104 in the same plane as select block 104 can be biased with an erase voltage (Vers), such as a high positive bias voltage (e.g., 20 V or more). Memory cells 106 of adjacent NAND memory strings 108 can be coupled through word lines 118 that select which row of memory cells 106 is affected by read and program operations. In some implementations, each word line 118 is coupled to a plurality of memory cells 106. Each word line 118 can include a plurality of control gates (gate electrodes) at each memory cell 106 and a gate line coupling the control gates.

As shown in FIG. 1, memory cell array 101 can include an array of memory cells 106 in a plurality of rows and a plurality of columns in each block 104. One column of memory cells corresponds to one NAND memory string 108, according to some implementations. The plurality of rows of memory cells 106 can be respectively coupled to word lines 118, and the plurality of columns of memory cells 106 can be respectively coupled to bit lines 116. Peripheral circuit 102 can be coupled to memory cell array 101 through bit lines 116 and word lines 118.

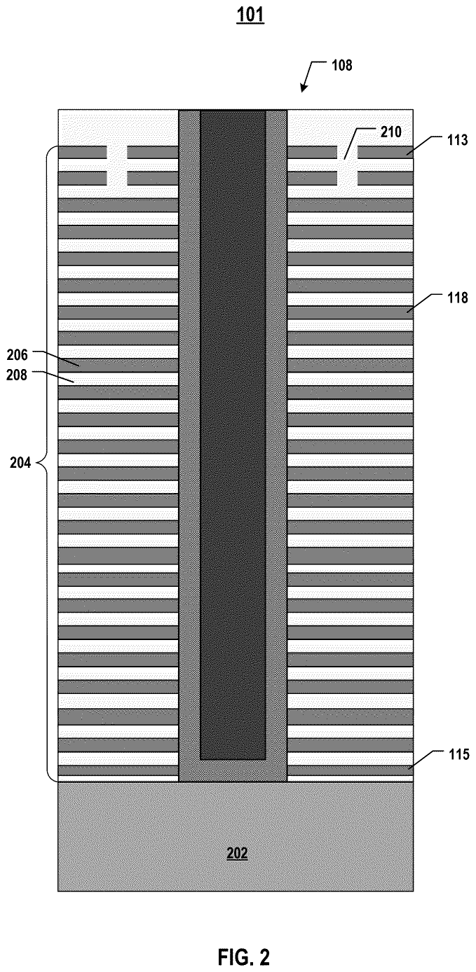

FIG. 2 illustrates a side view of a cross-section of memory cell array 101 including NAND memory string 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding memory cells 106, the gates of DSG transistors 112, or the gates of SSG transistors 110, and can extend laterally as DSG line 113 at the top of memory stack 204, SSG line 115 at the bottom of memory stack 204, or word line 118 between DSG line 113 and SSG line 115.

In some implementations, DSG cuts 210 (a.k.a., TSG cuts) are formed through DSG lines 113, which electrically separate DSG lines 113 between adjacent areas (e.g., “sets” referred to herein), such that DSG lines 113 and DSG transistors 112 in different sets may be individually controlled in read and/or program operations.

As shown in FIG. 2, NAND memory string 108 includes a channel structure extending vertically through memory stack 204. In some implementations, the channel structure includes a channel hole filled with semiconductor material(s) (e.g., as a semiconductor channel) and dielectric material(s) (e.g., as a memory film). It is understood that although not shown in FIG. 2, additional components of memory cell array 101 can be formed including, but not limited to, gate line slits/source contacts, local contacts, interconnect layers, etc.

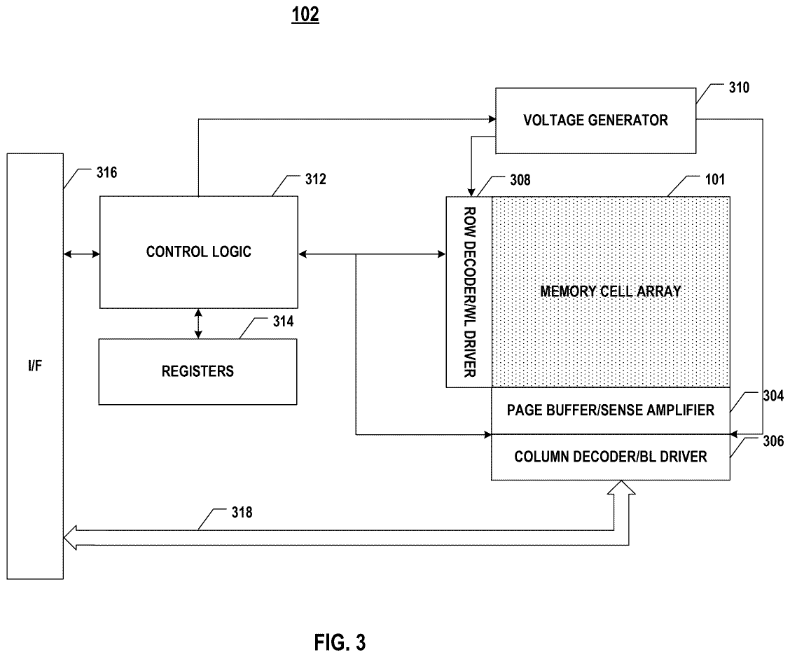

Referring back to FIG. 1, peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each select memory cell 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some exemplary peripheral circuits including a page buffer/sense amplifier 304, a column decoder/bit line driver 306, a row decoder/word line driver 308, a voltage generator 310, control logic 312, registers 314, an interface (I/F) 316, and a data bus 318. It is understood that in some examples, additional peripheral circuits not shown in FIG. 3 may be included as well.

Page buffer/sense amplifier 304 can be configured to sense (read) and program (write) data from and to memory cell array 101 according to the control signals from control logic 312. In one example, page buffer/sense amplifier 304 may store one or more pages of program data (write data, also referred to herein as “data page”) to be programmed. In another example, page buffer/sense amplifier 304 may verify programmed select memory cells 106 in each program/verify cycle in a program operation to ensure that the data has been properly programmed into memory cells 106 coupled to select word lines 118. In still another example, page buffer/sense amplifier 304 may also sense the low power signals from bit line 116 that represents a data bit stored in memory cell 106 and amplify the small voltage swing to recognizable logic levels in a read operation.

Column decoder/bit line driver 306 can be configured to be controlled by control logic 312 and select one or more NAND memory strings 108 by applying bit line voltages generated from voltage generator 310. Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Voltage generator 310 can be configured to be controlled by control logic 312 and generate the word line voltages (e.g., read voltage, program voltage, channel pass voltage, local voltage, verify voltage, etc.), bit line voltages, and source line voltages to be supplied to memory cell array 101.

Control logic 312 can be coupled to each peripheral circuit described above and configured to control the operations of each peripheral circuit. Registers 314 can be coupled to control logic 312 and include status registers, command registers, and address registers for storing status information, command operation codes (OP codes), and command addresses for controlling the operations of each peripheral circuit. Interface 316 can be coupled to control logic 312 and act as a control buffer to buffer and relay control commands received from a memory controller (not shown) and/or a host (not shown) to control logic 312 and status information received from control logic 312 to the memory controller and/or the host. Interface 316 can also be coupled to column decoder/bit line driver 306 via data bus 318 and act as a data input/output (I/O) interface and a data buffer to buffer and relay the data to and from memory cell array 101.

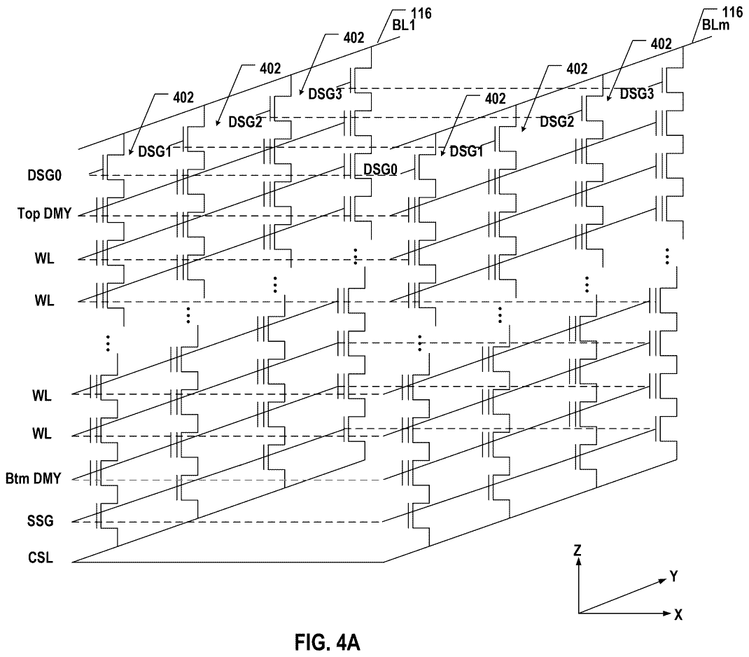

FIGS. 4A and 4B illustrate schematic diagrams of 3D NAND memory strings, according to some aspects of the present disclosure. FIGS. 4A and 4B show an example of an array of 3D NAND memory strings (e.g., 108 in FIG. 1) in a block (e.g., 104 in FIG. 1). As shown in FIG. 4A, from top to bottom in the z-direction, each 3D NAND memory string may be coupled to a number of lines in different rows, e.g., DSG lines (DSGs, e.g., 113 in FIG. 1), dummy DSG lines (top DMYs), word lines (WLs, e.g., 118 in FIG. 1), dummy SSG lines (bottom DMYs), SSG line (SSG, e.g., 115 in FIG. 1), and common source line (CSL, e.g., 114 in FIG. 1). As shown in FIG. 4A, in both the word line direction (the x-direction) and the bit line direction (the y-direction), the word lines may extend laterally to connect the memory cells of the 3D NAND memory strings. As to the DSG lines, the DSG lines may be continuous in the word line direction (the x-direction) to connect the DSG transistors of the 3D NAND memory strings at the same position in the y-direction (e.g., DSG0 and DSG0), but may be separated by DSG cuts 402 in the bit line direction (the y-direction) to form electrically-separated sets, respectively, which can be individually controlled in a program operation.

An array of 3D NAND memory strings can be divided into multiple sets in the bit line direction (the y-direction) by DSG cuts 402 that electrically separate DSG line(s) and DSG transistors (e.g., each of DSG0, DSG1, DSG2, and DSG3 is separated in FIGS. 4A and 4B). As a result, each set of 3D NAND memory strings may be individually controlled in a program operation by individually selected and controlling the respective DSG line. As shown in FIGS. 4A and 4B, the array of 3D NAND memory strings may be divided by 3 DSG cuts 402 into 4 sets each including the 3D NAND memory strings having DSG0, DSG1, DSG2, and DSG3, respectively. Each bit line 116 (BL1, . . . BLm) can be coupled to multiple sets of 3D NAND memory strings. Consistent with the scope of the present disclosure, in some implementations, an array of 3D memory strings are divided into sets by DSG cuts 402 in a program operation, and each set is the basic unit for program operation for implementing program operation schemes, such as SLC programming scheme.

It is understood that DSG cuts 402 may be implemented as physical cuts that replace parts of the DSG lines with dielectric layers (e.g., DSG cuts 210 shown in FIG. 2), or may be implemented as electrical cuts that pre-program (a.k.a. trim) different DSG transistors to different threshold voltage levels. It is also understood that the interval between adjacent DSG cuts 402 (i.e., the number of 3D NAND memory strings in each set) may vary in different examples.

As shown in FIG. 4B, page buffer/sense amplifier 304 can include a plurality of page buffer circuits 406 each coupled to a respective one of bit lines 116. In other words, each page buffer circuit 406 can be coupled to multiple sets of 3D NAND memory strings (e.g., having DSG0, DSG1, DSG2, and DSG3) through a respective bit line 116 and configured to temporarily store N bits of data in N data latches 408. Consistent with the scope of the present disclosure, in some implementations, all page buffer circuits 406 together in page buffer/sense amplifier 304 temporarily store N pages of data for programming in a program operation, for example, in an SLC mode, as described below in detail.

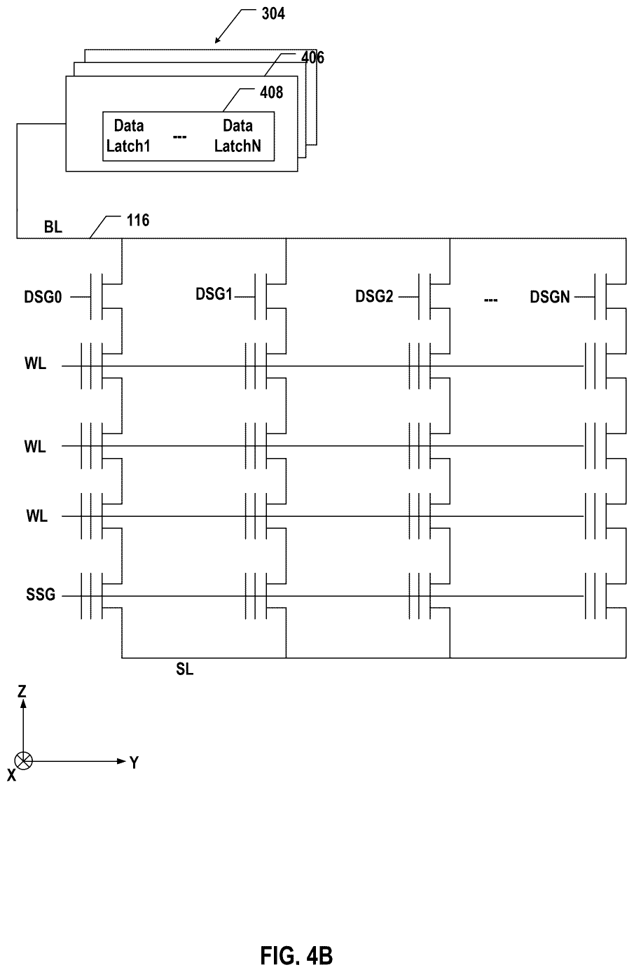

To perform a program operation, in addition to page buffer/sense amplifier 304 for providing data, row decoder/word line driver 308 can be configured to apply program voltages and verify voltages to a select word line 118 coupled to a select row of memory cells 106 in one or more program/verify cycles in order to raise the threshold voltage of each select memory cell 106 to a desired level (into a desired range of threshold voltages) based on the corresponding piece of data. For example, FIGS. 5A and 5B illustrate a waveform of word line voltages applied to a select word line in a program operation in an SLC mode, according to some aspects of the present disclosure.

As shown in FIGS. 5A and 5B, the program operation in the SLC mode includes one or more loops 502, each of which includes a program cycle 504 and a verify cycle 506, according to some implementations. As shown in FIG. 5B, in each loop 502, row decoder/word line driver 308 can be configured to apply a program voltage (Vpgm) on select word line 118 to select row of memory cells 106 in program cycle 504 and sequentially apply one or more verify voltages (Vvfy) with incremental changes of voltage levels to verify select row of memory cells 106 in verify cycle 506. That is, in each loop 502, peripheral circuit 102 can perform verification of select row of memory cells 106 in verify cycle 506 after applying a program voltage in program cycle 504. As a result, at the end of the program operation, for example, select memory cell 106 can be programmed into one of the two levels (programmed state or erased state).

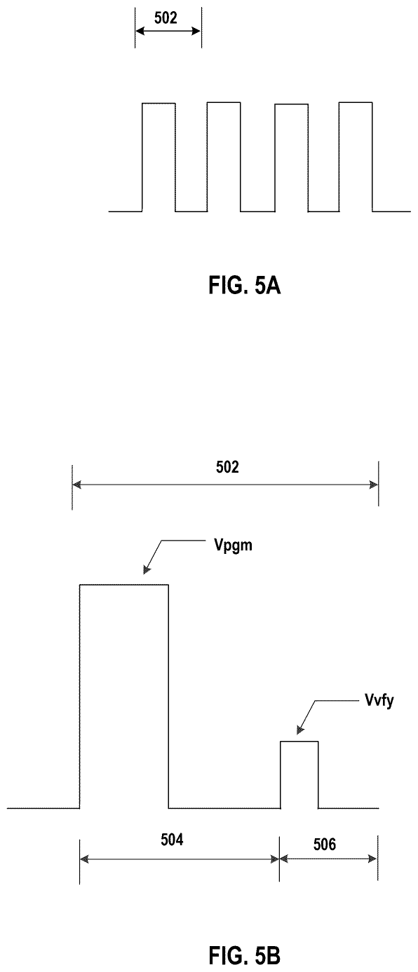

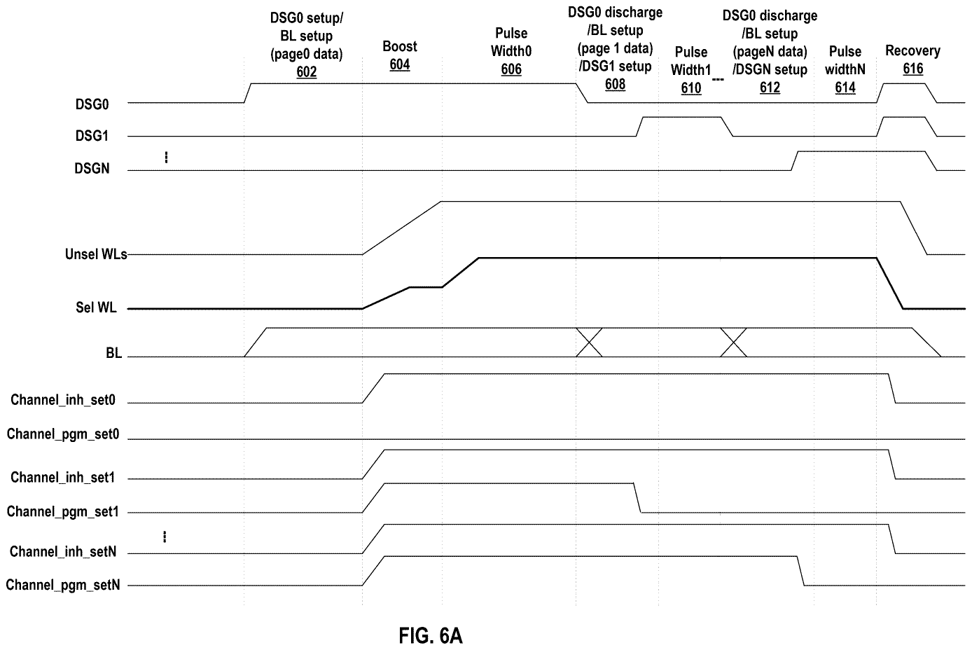

FIG. 6A illustrates timing diagrams of a program operation in an SLC mode, according to some aspects of the present disclosure. FIG. 6A shows an example of a program cycle 504 of a program operation in an SLC mode (SLC programming), according to some implementations. In period 602 of the program operation, the DSG transistors of NAND memory strings of a first set can be turned on or off by setting up the DSG voltage on a first DSG line (DSG0) and the bit line voltage on each bit line (BL). In some implementations, in period 602, an on voltage is applied to the first DSG line (DSG0), which is coupled to the DSG transistors of NAND memory strings of the first set (referred to herein as “first set of memory strings”), to turn on or off the DSG transistors of the first set of memory strings, depending on whether the memory string is in the program state or inhibit state determine by the corresponding bit line voltage. The voltage on the first DSG line can be ramped up from an off voltage to the on voltage in period 602. The on voltage may be equal to or larger than the threshold voltages of the DSG transistors of the first set of memory strings, while the off voltage may be smaller than the threshold voltages, for example, the negative supply voltage (Vss) or the ground voltage (0 V). In some implementations, in period 602, a bit line voltage is applied to each bit line, which is coupled to the first set of memory strings to program the corresponding memory strings (such that the corresponding memory strings are in the program state) or inhibit the corresponding memory strings from programming (such that the corresponding memory strings are in the inhibit state), depending on the voltage level of each bit line. In some implementations, the on voltage on the first DSG line in conjunction with a bit line voltage at the ground level (0 V) can turn on the DSG transistors of the first set of memory strings in the program state and load the first page of data (page0) to the select memory cells of the first set of memory strings in the program state. The select memory cells are coupled to the select word line (Sel WL), according to some implementations. In some implementations, in contrast, the on voltage on the first DSG line in conjunction with a bit line voltage at a positive level can turn off the DSG transistors of the first set of memory strings in the inhibit state. As shown in FIG. 6A, the voltage signals on other DSG lines (e.g., DSG1 and DSGN) and word lines remain at the negative supply voltage (Vss) or the ground voltage (0 V) in period 602, and the channel potentials of all the NAND memory strings are not boosted, i.e., at a non-boosted level in period 602, according to some implementations.

As shown in FIG. 6A, in period 604 of the program operation immediately after period 602, the voltage signals on the word lines, including the select word line and each of the unselect word lines (Unsel WLs), are boosted (e.g., ramping up the word line voltages on word lines WL shown in FIG. 4B). In some implementations, in period 604, the word line voltage on the select word line is ramped up from the negative supply voltage (Vss) or the ground voltage (0 V) to an intermediate voltage level, and the word line voltage on each unselect word line is ramped up from the negative supply voltage (Vss) or the ground voltage (0 V) to a pass voltage level. That is, a pass voltage pulse on the unselect word line can be ramped up to the pass voltage level and maintained at the pass voltage level in period 604. Since the DSG transistors of the first set of memory strings in the program state are turned on in period 604, the channel potential is determined by the bit line voltage, e.g., the ground level (0 V), to be at a non-boosted level. In contrast, for all other NAND memory strings, since their DSG transistors are still turned off, their channel potentials are determined by the word line voltages to be at a boosted level. For example, the intermediate voltage level and the pass voltage level may be sufficient to boost the channel potentials of all the NAND memory strings except the first set of memory strings in the program state (Channel_pgm_set0), from the non-boosted level to a boosted level in period 604. As shown in FIG. 6A, the voltage signal on the first DSG line is maintained at the on voltage, while the voltage signals on other DSG lines (e.g., DSG1 and DSGN) remain at the negative supply voltage (Vss) or the ground voltage (0 V) in period 604, according to some implementations.

As shown in FIG. 6A, in period 606 of the program operation immediately after period 604, the voltage signal on the select word line reaches the program voltage level with a first duration/width (pulse width0). In some implementations, in period 606, the word line voltage on the select word line is ramped up from the intermediate voltage level to the program voltage level. That is, a program voltage pulse on the select word line can be ramped up to the program voltage level and maintained at the program voltage level in period 606 for a first duration. The program voltage level may be sufficiently high compared with the channel potential (the non-boosted level) of the first set of memory strings in the program state (Channel_pgm_set0) to program the select memory cells of the first set of memory strings in the program state in period 606, while the program voltage level may not be too high compared with the channel potential (the boosted level) of other NAND memory strings in the inhibit state to inhibit programming of these memory strings in period 606. The pass voltage pulse on the unselect word line is maintained at the same pass voltage level in period 606, according to some implementations. As shown in FIG. 6A, the voltage signal on the first DSG line is maintained at the on voltage, while the voltage signals on other DSG lines (e.g., DSG1 and DSGN) remain at the negative supply voltage (Vss) or the ground voltage (0 V) in period 606, according to some implementations. Thus, the channel potentials of all the NAND memory strings except the first set of memory strings in the program state (Channel_pgm_set0) are at the boosted level in period 606. Thus, the select memory cells of the first set of memory strings in the program state can be programmed in period 606 for the first duration based on the first page of data (page0).

As shown in FIG. 6A, in period 608 of the program operation immediately after period 606, the DSG transistors of NAND memory strings of a second set can be turned on or off by setting up the DSG voltage on a second DSG line (DSG1) and the bit line voltage on each bit line (BL) In some implementations, in period 608, an on voltage is applied to the second DSG line (DSG1), which is coupled to the DSG transistors of NAND memory strings of the second set (referred to herein as “second set of memory strings”), to turn on or off the DSG transistors of the second set of memory strings, depending on whether the memory string is in the program state or inhibit state determine by the corresponding bit line voltage. The voltage on the second DSG line can be ramped up from an off voltage to the on voltage in period 608. The on voltage may be equal to or larger than the threshold voltages of the DSG transistors of the second set of memory strings, while the off voltage may be smaller than the threshold voltages, for example, the negative supply voltage (Vss) or the ground voltage (0 V). In some implementations, in period 608, an off voltage is applied to the first DSG line (DSG0) to turn off the DSG transistors of the first set of memory strings. The off voltage may be smaller than the threshold voltages of the DSG transistors of the first set of memory strings, for example, the negative supply voltage (Vss) or the ground voltage (0 V). In other words, the first DSG line may be discharged in period 608. In some implementations, in period 608, the voltage signals on other DSG lines (e.g., DSGN) remain at the negative supply voltage (Vss) or the ground voltage (0 V). In some implementations, in period 608, a bit line voltage is applied to each bit line, which is coupled to the second set of memory strings to program the corresponding memory strings (such that the corresponding memory strings are in the program state) or inhibit the corresponding memory strings from programming (such that the corresponding memory strings are in the inhibit state), depending on the voltage level of each bit line. In some implementations, the on voltage on the second DSG line in conjunction with a bit line voltage at the ground level (0 V) can turn on the DSG transistors of the second set of memory strings in the program state and to load the second page of data (page1) to the select memory cells of the second set of memory strings in the program state. The select memory cells are coupled to the select word line, according to some implementations. In some implementations, in contrast, the on voltage on the second DSG line in conjunction with a bit line voltage at a positive level can turn off the DSG transistors of the second set of memory strings in the inhibit state.

Since the DSG transistors of the second set of memory strings in the program state are turned on in period 608, the channel potential is determined by the bit line voltage, e.g., the ground level (0 V), to be at a non-boosted level. In contrast, for all other NAND memory strings except the first and second sets of memory strings in the program state, since their DSG transistors are still turned off, their channel potentials are determined by the word line voltages to be at a boosted level. That is, the channel potentials of all the NAND memory strings except the first and second sets of memory strings in the program state (Channel_pgm_set0 and Channel_pgm_set1) are at the boosted level in period 606.

Consistent with the scope of the present disclosure, in period 608, the program voltage pulse on the select word line is maintained at the same program voltage level, and the pass voltage pulse on the unselect word line is maintained at the same pass voltage level, according to some implementations. In other words, in some implementations, the word line voltages on the select word line and unselect word lines do not alter during period 608.

As shown in FIG. 6A, in period 610 of the program operation immediately after period 608, the voltage signal on the select word line is maintained at the program voltage level with a second duration/width (pulse width1). In some implementations, in period 610, the program voltage pulse on the select word line is maintained at the same program voltage level for a second duration. The program voltage level may be sufficiently high compared with the channel potential (the non-boosted level) of the second set of memory strings in the program state (Channel_pgm_set1) to program the select memory cells of the second set of memory strings in the program state in period 610 as well, while the program voltage level may not be too high compared with the channel potential (the boosted level) of other NAND memory strings in the inhibit state to inhibit programming of these memory strings in period 610. The pass voltage pulse on the unselect word line is maintained at the same pass voltage level in period 610, according to some implementations. As shown in FIG. 6A, the voltage signal on the second DSG line is maintained at the on voltage, while the voltage signals on other DSG lines (e.g., DSG0 and DSGN) remain at the negative supply voltage (Vss) or the ground voltage (0 V) in period 610, according to some implementations. Thus, the channel potentials of all the NAND memory strings except the first and second sets of memory strings in the program state (Channel_pgm_set0 and Channel_pgm_set1) are at the boosted level in period 610. Thus, the select memory cells of the second set of memory strings in the program state can be programmed in period 610 for the second duration based on the second page of data (page1). It is understood that since the channel potential of the first set of memory strings in the program state (Channel_pgm_set0) may be at the non-boosted level in period 610, like the second set of memory strings in the program state (Channel_pgm_set1), the select memory cells of the first set of memory strings in the program state may be programmed again in period 610 for the second duration.

As shown in FIG. 6A, in period 612 of the program operation after period 610, the DSG transistors of NAND memory strings of a Nth set can be turned on or off by setting up (the DSG voltage on a Nth DSG line (DSGN) and the bit line voltage on each bit line (BL). It is understood that period 612 may be or may not be immediately after period 610, depending on, for example, the number of sets of NAND memory strings in the block for the program operation. In some implementations, in period 612, an on voltage is applied to the Nth DSG line (DSGN), which is coupled to the DSG transistors of NAND memory strings of the Nth set (referred to herein as “Nth set of memory strings”), to turn on or off the DSG transistors of the Nth set of memory strings, depending on whether the memory string is in the program state or inhibit state determine by the corresponding bit line voltage. The voltage on the Nth DSG line can be ramped up from an off voltage to the on voltage in period 612. The on voltage may be equal to or larger than the threshold voltages of the DSG transistors of the Nth set of memory strings, while the off voltage may be smaller than the threshold voltages, for example, the negative supply voltage (Vss) or the ground voltage (0 V). In some implementations, in period 612, the off voltage is applied to the second DSG line (DSG1) to turn off the DSG transistors of the second set of memory strings. In other words, the second DSG line may be discharged in period 612. In some implementations, in period 612, the voltage signal on the first DSG line (DSG0) remains at the negative supply voltage (Vss) or the ground voltage (0 V). In some implementations, in period 612, a bit line voltage is applied to each bit line, which is coupled to the Nth set of memory strings to program the corresponding memory strings (such that the corresponding memory strings are in the program state) or inhibit the corresponding memory strings from programming (such that the corresponding memory strings are in the inhibit state), depending on the voltage level of each bit line. In some implementations, the on voltage on the Nth DSG line in conjunction with a bit line voltage at the ground level (0 V) can turn on the DSG transistors of the Nth set of memory strings in the program state and to load the Nth page of data (pageN) to the select memory cells of the Nth set of memory strings in the program state. The select memory cells are coupled to the select word line, according to some implementations. In some implementations, in contrast, the on voltage on the Nth DSG line in conjunction with a bit line voltage at a positive level can turn off the DSG transistors of the Nth set of memory strings in the inhibit state.

Since the DSG transistors of the Nth set of memory strings in the program state are turned on in period 612, the channel potential is determined by the bit line voltage, e.g., the ground level (0 V), to be at a non-boosted level. In contrast, for NAND memory strings in the inhibit state, since their DSG transistors are still turned off, their channel potentials are determined by the word line voltages to be at a boosted level. That is, the channel potentials of all the NAND memory strings in the inhibit state are at the boosted level in period 612.

Consistent with the scope of the present disclosure, in period 612, the program voltage pulse on the select word line is maintained at the same program voltage level, and the pass voltage pulse on the unselect word line is maintained at the same pass voltage level, according to some implementations. In other words, in some implementations, the word line voltages on the select word line and unselect word lines do not alter during period 612.

As shown in FIG. 6A, in period 614 of the program operation immediately after period 612, the voltage signal on the select word line is maintained at the program voltage level with an Nth duration/width (pulse widthN). In some implementations, in period 614, the program voltage pulse on the select word line is maintained at the same program voltage level for an Nth duration. The program voltage level may be sufficiently high compared with the channel potential (the non-boosted level) of the Nth set of memory strings in the program state (Channel_pgm_setN) to program the select memory cells of the Nth set of memory strings in the program state in period 614 as well, while the program voltage level may not be too high compared with the channel potential (the boosted level) of other NAND memory strings in the inhibit state to inhibit programming of these memory strings in period 614. The pass voltage pulse on the unselect word line is maintained at the same pass voltage level in period 614, according to some implementations. As shown in FIG. 6A, the voltage signal on the Nth DSG line is maintained at the on voltage, while the voltage signals on other DSG lines (e.g., DSG0 and DSG1) remain at the negative supply voltage (Vss) or the ground voltage (0 V) in period 614, according to some implementations. Thus, the channel potentials of all the NAND memory strings in the inhibit state are at the boosted level, while the channel potentials of all the NAND memory strings in the program state are at the non-boosted level in period 612, according to some implementations. Thus, the select memory cells of the Nth set of memory strings in the program state can be programmed in period 614 for the Nth duration based on the Nth page of data (pageN). It is understood that since the channel potential of the first and second sets of memory strings in the program state (Channel_pgm_set0 and Channel_pgm_set1) may be at the non-boosted level in period 614, like the Nth set of memory strings in the program state (Channel_pgm_setN), the select memory cells of the first and second sets of memory strings in the program state may be programmed again in period 614 for the Nth duration.

As shown in FIG. 6A, in period 616 of the program operation immediately after period 616, the NAND memory strings in the block undergoing the program operation are recovered from programming and get ready for another operation (e.g., read operation or another program operation). In period 616, the on voltages are applied to all the DSG lines (e.g., DSG0, DSG1, and DSGN), and the program voltage pulse and pass voltage pulse on the select word line and each unselect word line, respectively, are discharged, according to some implementations. For example, in period 616, the program voltage pulse on the select word line may be ramped down from the program voltage level to the negative supply voltage (Vss) or the ground voltage (0 V), and the pass voltage pulse on the unselect word line may be ramped down from the pass voltage level to the negative supply voltage (Vss) or the ground voltage (0 V). Similarly, in period 616, the bit line voltage on the bit line is discharged, according to some implementations. The channel potentials of all the NAND memory strings are at the non-boosted level in period 616.

Consistent with the scope of the present disclosure, a continuous program voltage pulse can be applied to the select word line between the boosting period (606) and the recovery period (616), for example, during each of the pulse width periods (e.g., 606, 601, and 614) of the program operation. Similarly, a continuous pass voltage pulse can be applied to each unselect word line between the boosting period (606) and the recovery period (616), for example, during each of the pulse width periods (e.g., 606, 601, and 614) of the program operation. In other words, there is only one boosting period and one recovery period for the program operation during which the word line voltage applied on a word line needs to alter (e.g., ramping up or ramping down), according to some implementations. Therefore, the time duration of the program operation (tPROG) can be reduced by reducing the number of boosting and recovery periods.

It is understood that except the Nth set of memory strings that are programmed lastly (in pulse width period 614 immediately before recovery), all other sets of memory strings in the program state may be programmed in multiple pulse width periods. For example, the first set of memory strings in the program state may be programmed in each pulse width period (e.g., 606, 610, and 614). In other words, different sets of memory strings in the program state may be programmed for different durations. Thus, the durations of different pulse width periods can be set differently to compensate for the inconsistency of programming durations among different sets of memory strings in the program state. In some implementations, the later the pulse width period in the program operation, the longer its duration is. For example, the Nth duration of pulse width period 614 may be longer than the second duration of pulse width period 610, which may be longer than the first duration of pulse width period 606.

The voltage levels of the continuous program voltage pulse in different pulse width periods can be set differently to compensate for the inconsistency of programming durations among different sets of memory strings as well. In some implementations, as shown in FIG. 6B, in the last pulse width period immediately before recovery (e.g., period 614), the program voltage pulse on the select word line is ramped up to a higher level than that in the previous pulse width periods (e.g., 606 and 610), and maintained at the higher level for programming the select memory cells of the Nth set of memory strings in the program state.

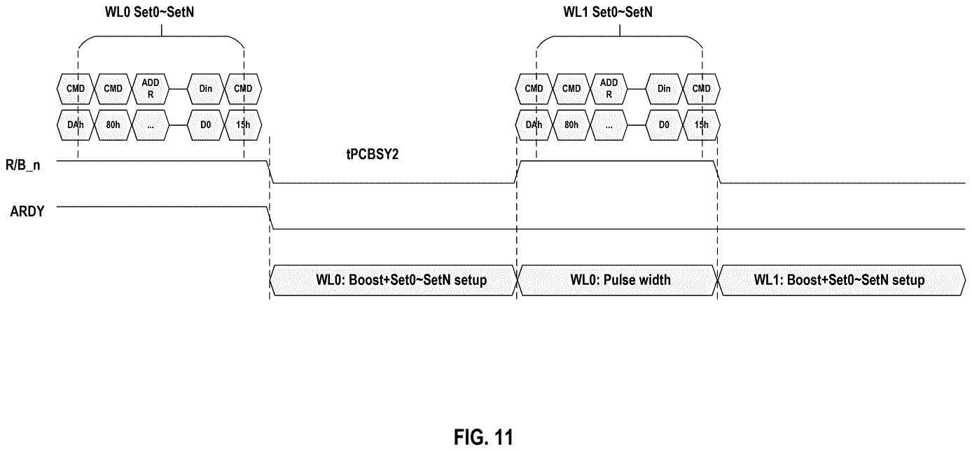

FIG. 12 illustrates a flowchart of a method 1200 for programming a memory device, according to some aspects of the present disclosure. The memory device may be any suitable memory device disclosed herein, such as memory device 100. Method 1200 may be implemented by peripheral circuit 102, such as row decoder/word line driver 308, page buffer/sense amplifier 304, and control logic 312. It is understood that the operations shown in method 1200 may not be exhaustive and that other operations can be performed as well before, after, or between any of the illustrated operations. Further, some of the operations may be performed simultaneously, or in a different order than shown in FIG. 12.

Referring to FIG. 12, method 1200 starts at operation 1202, in which in a first period of a program operation, an on voltage is applied to a first DSG line coupled to the DSG transistor of a first memory string of the memory strings, and an off voltage is applied to a second DSG line coupled to the DSG transistor of a second memory string of the memory strings. The first memory string is in the first set of memory strings in the program state, and the second memory string is in the second set of memory strings in the program state. For example, as shown in FIGS. 1-3, 6A, and 6B, in period 606, word line driver 308 of peripheral circuit 102 may be configured to apply the on voltage to the first DSG line (DSG0), and apply the off voltage to the second DSG line (DSG1).

Method 1200 proceeds to operation 1204, as illustrated in FIG. 12, in which in a second period of the program operation after the first period, an on voltage is applied to the second DSG line coupled to the DSG transistor of the second memory string, and an off voltage is applied to the first DSG line coupled to the DSG transistor of the first memory string. For example, as shown in FIG. 1-3, 6A, and 6B, in period 610, word line driver 308 of peripheral circuit 102 may be configured to apply the on voltage to the second DSG line (DSG1), and apply the off voltage to the first DSG line (DSG0).

Method 1200 proceeds to operation 1206, as illustrated in FIG. 12, in which a continuous program voltage pulse is applied to a select word line during the first period and the second period of the program operation. In some implementations, the select word line is coupled to a first memory cell of the memory cells in the first memory string and a second memory cell of the memory cells in the second memory string. For example, as shown in FIGS. 1-3, 6A, and 6B, word line driver 308 of peripheral circuit 102 may be configured to apply the continuous program voltage pulse to the select word line (Sel WL) during period 606 and period 610.

In some implementations, to apply the continuous program voltage pulse to the select word line, the program voltage pulse on the select word line is ramped up to a first level in the first period, and the program voltage pulse on the select word line is maintained at the first level in the second period. For example, as shown in FIG. 1-3, 6A, and 6B, word line driver 308 of peripheral circuit 102 may be configured to ramp up the program voltage pulse on the select word line to the program voltage level in period 606, and maintain the program voltage pulse at the program voltage level in period 610.

Method 1200 proceeds to operation 1208, as illustrated in FIG. 12, in which a continuous pass voltage pulse is applied to an unselect word line during the first period and the second period of the program operation. For example, as shown in FIG. 1-3, 6A, and 6B, word line driver 308 of peripheral circuit 102 may be configured to apply the continuous pass voltage pulse to each unselect word line (Unsel WLs) during period 606 and period 610.

In some implementations, to apply the continuous pass voltage pulse to the unselect word line, the pass voltage pulse on the unselect word line is ramped up to a second level before the first period, and the pass voltage pulse on the unselect word line is maintained at the second level in the first and second periods. For example, as shown in FIG. 1-3, 6A, and 6B, word line driver 308 of peripheral circuit 102 may be configured to ramp up the pass voltage pulse on the unselect word line to the pass voltage level in period 604 before period 606, and maintain the pass voltage pulse at the pass voltage level in period 606 and period 610.

Method 1200 proceeds to operation 1210, as illustrated in FIG. 12, in which a bit line voltage is applied to a bit line during the first period and the second period of the program operation. In some implementations, the bit line is coupled to the first memory cell and the second memory cell. In some implementations, the bit line voltage is at a ground level, such that the first and second memory strings are at the program state. For example, as shown in FIG. 1-3, 6A, and 6B, page buffer 304 of peripheral circuit 102 may be configured to apply the bit line voltage to the bit line (BL) during period 606 and period 610 to in period 606 load the first page of data (data0), and in period 610 load the second page of data (data1).

Method 1200 proceeds to operation 1212, as illustrated in FIG. 12, in which in a third period of the program operation after the second period, an on voltage is applied to a third DSG line coupled to the DSG transistor of a third memory string of the memory strings, and the off voltages are applied to the first and second DSG lines coupled to the DSG transistors of the first and second memory strings, respectively. The third memory string is in the third set of memory strings in the program state. For example, as shown in FIG. 1-3, 6A, and 6B, in period 614, word line driver 308 of peripheral circuit 102 may be configured to apply the on voltage to the Nth DSG line (DSGN), and apply the off voltages to the first and second DSG lines (DSG0 and DSG1).

Method 1200 proceeds to operation 1214, as illustrated in FIG. 12, in which the continuous program voltage pulse is applied to the select word line during the third period of the program operation. For example, as shown in FIG. 1-3, 6A, and 6B, in period 614, word line driver 308 of peripheral circuit 102 may be configured to apply the continuous program voltage pulse to the select word line (Sel WL) during period 614.

In some implementations, the third period is longer than the second period. For example, as shown in FIG. 6B, period 614 is longer than period 610.

In some implementations, to apply the continuous program voltage pulse to the select word line during the third period of the program operation, the program voltage pulse on the select word line is ramped up to a third level in the third period, and the program voltage pulse on the select word line is maintained at the third level in the third period. For example, as shown in FIG. 1-3 and 6B, in period 614, word line driver 308 of peripheral circuit 102 may be configured to ramp up the continuous program voltage pulse on the select word line to the higher level, and maintain the continuous program voltage pulse on the select word line at the higher level.

In some implementations, in a fourth period of the program operation after the third period, the on voltages are applied to the first, second, and third DSG lines coupled to the DSG transistors of the first, second, and third memory strings, respectively, and the program voltage pulse on the select word line is discharged. For example, as shown in FIG. 1-3, 6A, and 6B, in period 616, word line driver 308 of peripheral circuit 102 may be configured to apply the on voltages to the first, second, and Nth DSG lines (DSG0, DSG1, and DSGN), and discharge the program voltage pulse on the select word line (Sel WL).

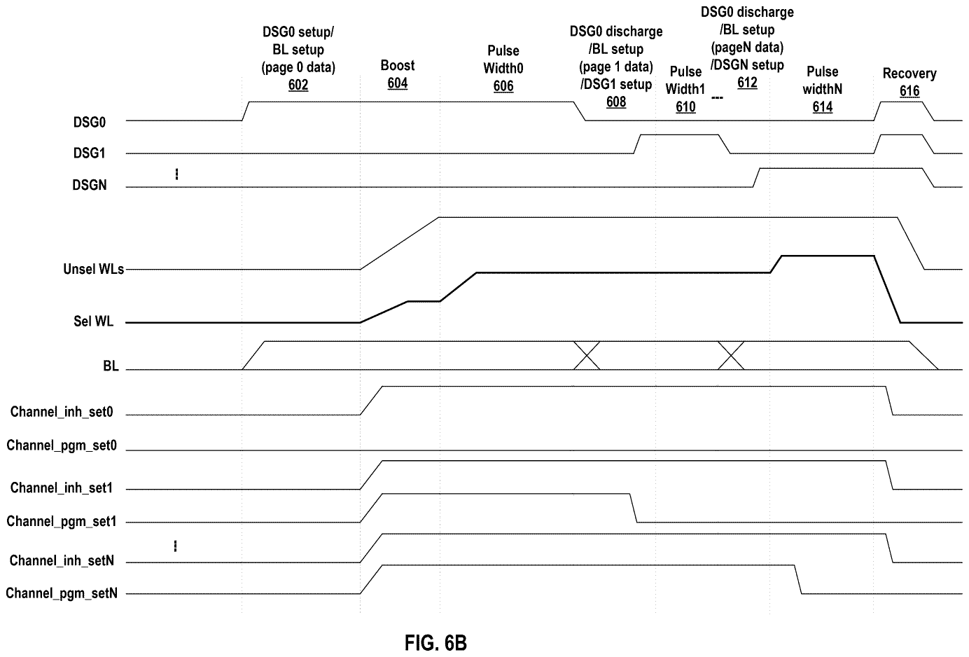

FIG. 7 illustrates timing diagrams of still another program operation in an SLC mode, according to some aspects of the present disclosure. FIG. 7 shows an example of a program cycle 504 of a program operation in an SLC mode (SLC programming), according to some implementations. In period 702 of the program operation, the DSG transistors of NAND memory strings of a first set can be turned on or off by setting up the DSG voltage on a first DSG line (DSG0) and the bit line voltage on each bit line (BL). In some implementations, in period 702, an on voltage is applied to the first DSG line (DSG0), which is coupled to the DSG transistors of NAND memory strings of the first set (referred to herein as “first set of memory strings”), to turn on or off the DSG transistors of the first set of memory strings, depending on whether the memory string is in the program state or inhibit state determine by the corresponding bit line voltage. The voltage on the first DSG line can be ramped up from an off voltage to the on voltage in period 702. The on voltage may be equal to or larger than the threshold voltages of the DSG transistors of the first set of memory strings, while the off voltage may be smaller than the threshold voltages, for example, the negative supply voltage (Vss) or the ground voltage (0 V). In some implementations, in period 702, a bit line voltage is applied to each bit line (BL), which is coupled to the first set of memory strings to program the corresponding memory strings (such that the corresponding memory strings are in the program state) or inhibit the corresponding memory strings from programming (such that the corresponding memory strings are in the inhibit state), depending on the voltage level of each bit line. In some implementations, the on voltage on the first DSG line in conjunction with a bit line voltage at the ground level (0 V) can turn on the DSG transistors of the first set of memory strings in the program state and load the first page of data (page0) to the select memory cells of the first set of memory strings in the program state. The select memory cells are coupled to the select word line (Sel WL), according to some implementations. In some implementations, in contrast, the on voltage on the first DSG line in conjunction with a bit line voltage at a positive level can turn off the DSG transistors of the first set of memory strings in the inhibit state. As shown in FIG. 7, the voltage signals on other DSG lines (e.g., DSG1 and DSGN) and word lines remain at the negative supply voltage (Vss) or the ground voltage (0 V) in period 702, and the channel potentials of all the NAND memory strings are not boosted, i.e., at a non-boosted level in period 702, according to some implementations.

As shown in FIG. 7, in period 704 of the program operation immediately after period 702, the voltage signals on the word lines, including the select word line and each of the unselect word lines (Unsel WLs), are boosted (e.g., ramping up the word line voltages on word lines WL shown in FIG. 4B). In some implementations, in period 704, the word line voltage on the select word line is ramped up from the negative supply voltage (Vss) or the ground voltage (0 V) to an intermediate voltage level, and the word line voltage on each unselect word line is ramped up from the negative supply voltage (Vss) or the ground voltage (0 V) to a pass voltage level. That is, a pass voltage pulse on the unselect word line can be ramped up to the pass voltage level and maintained at the pass voltage level in period 704. Since the DSG transistors of the first set of memory strings in the program state are turned on in period 704, the channel potential is determined by the bit line voltage, e.g., the ground level (0 V), to be at a boosted level. In contrast, for all other NAND memory strings, since their DSG transistors are still turned off, their channel potentials are determined by the word line voltages to be at a boosted level. For example, the intermediate voltage level and the pass voltage level may be sufficient to boost the channel potentials of all the NAND memory strings except the first set of memory strings in the program state (Channel_pgm_set0), from the non-boosted level to a boosted level in period 704. As shown in FIG. 7, the voltage signal on the first DSG line is maintained at the on voltage, while the voltage signals on other DSG lines (e.g., DSG1 and DSGN) remain at the negative supply voltage (Vss) or the ground voltage (0 V) in period 704, according to some implementations.

As shown in FIG. 7, in period 706 of the program operation immediately after period 704, the DSG transistors of NAND memory strings of a second set can be turned on or off by setting up the DSG voltage on a second DSG line (DSG1)and the bit line voltage on each bit line (BL). In some implementations, in period 706, an on voltage is applied to the second DSG line (DSG1), which is coupled to the DSG transistors of NAND memory strings of the second set (referred to herein as “second set of memory strings”), to turn on or off the DSG transistors of the second set of memory strings, depending on whether the memory string is in the program state or inhibit state determine by the corresponding bit line voltage. The voltage on the second DSG line can be ramped up from an off voltage to the on voltage in period 706. The on voltage may be equal to or larger than the threshold voltages of the DSG transistors of the second set of memory strings, while the off voltage may be smaller than the threshold voltages, for example, the negative supply voltage (Vss) or the ground voltage (0 V). In some implementations, in period 706, an off voltage is applied to the first DSG line (DSG0) to turn off the DSG transistors of the first set of memory strings. The off voltage may be smaller than the threshold voltages of the DSG transistors of the first set of memory strings, for example, the negative supply voltage (Vss) or the ground voltage (0 V). In other words, the first DSG line may be discharged in period 706. In some implementations, in period 706, the voltage signals on other DSG lines (e.g., DSGN) remain at the negative supply voltage (Vss) or the ground voltage (0 V). In some implementations, in period 706, a bit line voltage is applied to each bit line, which is coupled to the second set of memory strings to program the corresponding memory strings (such that the corresponding memory strings are in the program state) or inhibit the corresponding memory strings from programming (such that the corresponding memory strings are in the inhibit state), depending on the voltage level of each bit line. In some implementations, the on voltage on the second DSG line in conjunction with a bit line voltage at the ground level (0 V) can turn on the DSG transistors of the second set of memory strings in the program state and to load the second page of data (page1) to the select memory cells of the second set of memory strings in the program state. The select memory cells are coupled to the select word line, according to some implementations. In some implementations, in contrast, the on voltage on the second DSG line in conjunction with a bit line voltage at a positive level can turn off the DSG transistors of the second set of memory strings in the inhibit state.

Since the DSG transistors of the second set of memory strings in the program state are turned on in period 706, the channel potential is determined by the bit line voltage, e.g., the ground level (0 V), to be at a non-boosted level. In contrast, for all other NAND memory strings except the first and second sets of memory strings in the program state, since their DSG transistors are still turned off, their channel potentials are determined by the word line voltages to be at a boosted level. That is, the channel potentials of all the NAND memory strings except the first and second sets of memory strings in the program state (Channel_pgm_set0 and Channel_pgm_set1) are at the boosted level in period 606.

As shown in FIG. 7, in period 708 of the program operation after period 706, the DSG transistors of NAND memory strings of an Nth set can be turned on or off by setting up the DSG voltage on to an Nth DSG line (DSGN)the bit line voltage on each bit line (BL). It is understood that period 708 may be or may not be immediately after period 706, depending on, for example, the number of sets of NAND memory strings in the block for the program operation. In some implementations, in period 708, an on voltage is applied to the Nth DSG line (DSGN), which is coupled to the DSG transistors of NAND memory strings of the Nth set (referred to herein as “Nth set of memory strings”), to turn on or off the DSG transistors of the Nth set of memory strings, depending on whether the memory string is in the program state or inhibit state determine by the corresponding bit line voltage. The voltage on the Nth DSG line can be ramped up from an off voltage to the on voltage in period 708. The on voltage may be equal to or larger than the threshold voltages of the DSG transistors of the Nth set of memory strings, while the off voltage may be smaller than the threshold voltages, for example, the negative supply voltage (Vss) or the ground voltage (0 V). In some implementations, in period 708, the off voltage is applied to the second DSG line (DSG1) to turn off the DSG transistors of the second set of memory strings. In other words, the second DSG line may be discharged in period 708. In some implementations, in period 708, the voltage signal on the first DSG line (DSG0) remains at the negative supply voltage (Vss) or the ground voltage (0 V). In some implementations, in period 708, a bit line voltage is applied to each bit line, which is coupled to the Nth set of memory strings to program the corresponding memory strings (such that the corresponding memory strings are in the program state) or inhibit the corresponding memory strings from programming (such that the corresponding memory strings are in the inhibit state), depending on the voltage level of each bit line. In some implementations, the on voltage on the Nth DSG line in conjunction with a bit line voltage at the ground level (0 V) can turn on the DSG transistors of the Nth set of memory strings in the program state and to load the Nth page of data (pageN) to the select memory cells of the Nth set of memory strings in the program state. The select memory cells are coupled to the select word line, according to some implementations. In some implementations, in contrast, the on voltage on the Nth DSG line in conjunction with a bit line voltage at a positive level can turn off the DSG transistors of the Nth set of memory strings in the inhibit state.

Since the DSG transistors of the Nth set of memory strings in the program state are turned on in period 708, the channel potential is determined by the bit line voltage, e.g., the ground level (0 V), to be at a non-boosted level. In contrast, for NAND memory strings in the inhibit state, since their DSG transistors are still turned off, their channel potentials are determined by the word line voltages to be at a boosted level. That is, the channel potentials of all the NAND memory strings in the inhibit state are at the boosted level in period 708.

Consistent with the scope of the present disclosure, in periods 706 and 708, the program voltage pulse on the select word line is maintained at the same intermediate voltage level, and the pass voltage pulse on the unselect word line is maintained at the same pass voltage level, according to some implementations. In other words, in some implementations, the word line voltages on the select word line and unselect word lines do not alter during periods 706 and 708. The channel potentials of all the NAND memory strings in the inhibit state are at the boosted level, while the channel potentials of all the NAND memory strings in the program state are at the non-boosted level after period 708.

As shown in FIG. 7, in period 710 of the program operation immediately after period 708 (i.e., the last DSG/BL setup period), voltage signal on the select word line reaches the program voltage level with a duration/width (pulse width). In some implementations, in period 710, the word line voltage on the select word line is ramped up from the intermediate voltage level to the program voltage level. That is, a program voltage pulse on the select word line can be ramped up to the program voltage level and maintained at the program voltage level in period 710 for a duration. The program voltage level may be sufficiently high compared with the channel potential (the non-boosted level) of the memory strings in the program state (Channel_pgm_set0, Channel_pgm_set1, Channel_pgm_setN) to program all the select memory cells (e.g., of the first, second, and Nth sets of memory strings) in the program state in period 710, while the program voltage level may not be too high compared with the channel potential (the boosted level) of other NAND memory strings in the inhibit state to inhibit programming of these memory strings in period 710. The pass voltage pulse on the unselect word line is maintained at the same pass voltage level in period 710, according to some implementations. As shown in FIG. 7, the voltage signals on each DSG line (DSG0, DSG1, and DSGN) remain at the negative supply voltage (Vss) or the ground voltage (0 V) in period 710, according to some implementations. Thus, the channel potentials of all the NAND memory strings in the program state are at the non-boosted level in period 710. Thus, all the select memory cells (e.g., of the first, second, and Nth sets of memory strings) in the program state can be programmed in period 710 for the duration based on the 1st page of data (page 1), 2nd page of data (page2), and Nth page of data (pageN), respectively.

As shown in FIG. 7, in period 712 of the program operation immediately after period 710, the NAND memory strings in the block undergoing the program operation are recovered from programming and get ready for another operation (e.g., read operation or another program operation). In period 712, the on voltages are applied to all the DSG lines (e.g., DSG0, DSG1, and DSGN), and the program voltage pulse and pass voltage pulse on the select word line and each unselect word line, respectively, are discharged, according to some implementations. For example, in period 712, the program voltage pulse on the select word line may be ramped down from the program voltage level to the negative supply voltage (Vss) or the ground voltage (0 V), and the pass voltage pulse on the unselect word line may be ramped down from the pass voltage level to the negative supply voltage (Vss) or the ground voltage (0 V). Similarly, in period 712, the bit line voltage on the bit line is discharged, according to some implementations. The channel potentials of all the NAND memory strings are at the non-boosted level in period 712.

Consistent with the scope of the present disclosure, a program voltage pulse can be applied to the select word line in a single pulse width period (710) after all the DSG/BL setup periods (e.g., 702, 706, and 708), e.g., immediately after the last DSG/BL setup period (e.g., 708). A continuous pass voltage pulse can be applied to each unselect word line between the boosting period (606) and the recovery period (616). There is only one boosting period (704) and one recovery period (712) for the program operation during which the word line voltage applied on a word line needs to alter (e.g., ramping up or ramping down), according to some implementations. Therefore, the time duration of the program operation (tPROG) can be reduced by reducing the number of boosting and recovery periods. Moreover, different from the SLC programming scheme disclosed with respect to FIGS. 6A and 6B, in the SLC programming scheme disclosed with respect FIG. 7, all the select memory cells (e.g., of the first, second, and Nth sets of memory strings) in the program state can be programmed for the same duration in a single pulse width period (e.g., 710).

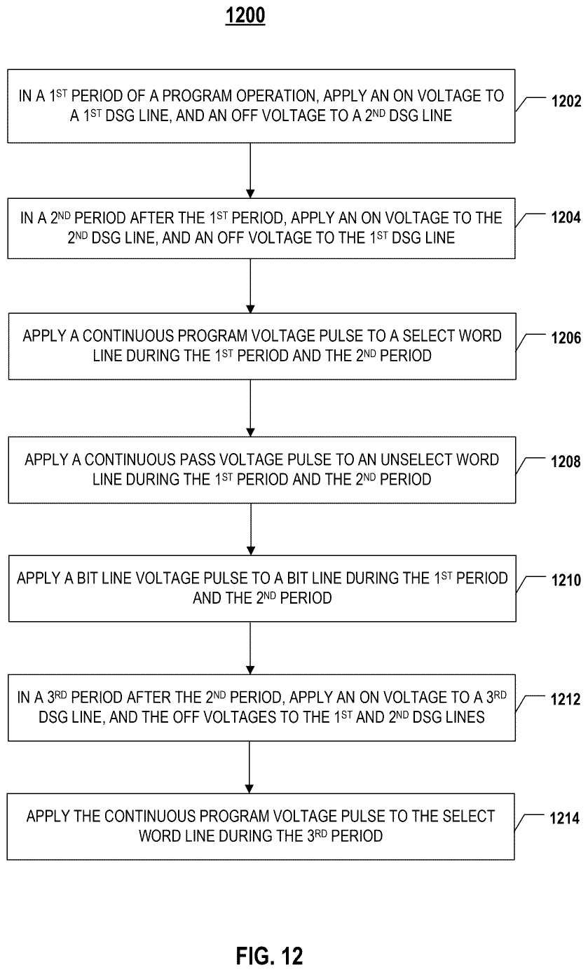

FIG. 13 illustrates a flowchart of another method 1300 for programming a memory device, according to some aspects of the present disclosure. The memory device may be any suitable memory device disclosed herein, such as memory device 100. Method 1300 may be implemented by peripheral circuit 102, such as row decoder/word line driver 308, page buffer/sense amplifier 304, and control logic 312. It is understood that the operations shown in method 1300 may not be exhaustive and that other operations can be performed as well before, after, or between any of the illustrated operations. Further, some of the operations may be performed simultaneously, or in a different order than shown in FIG. 13.

Referring to FIG. 13, method 1300 starts at operation 1302, in which in a first period of a program operation, an on voltage is applied to a first DSG line coupled to the DSG transistor of a first memory string of the memory strings, and an off voltage is applied to a second DSG line coupled to the DSG transistor of a second memory string of the memory strings. The first memory string is in the first set of memory strings in the program state, and the second memory string is in the second set of memory strings in the program state. For example, as shown in FIGS. 1-3 and 7 in period 702, word line driver 308 of peripheral circuit 102 may be configured to apply the on voltage to the first DSG line (DSG0), and apply the off voltage to the second DSG line (DSG1).

Method 1300 proceeds to operation 1304, as illustrated in FIG. 13, in which in a second period of the program operation after the first period, an on voltage is applied to the second DSG line coupled to the DSG transistor of the second memory string, and an off voltage is applied to the first DSG line coupled to the DSG transistor of the first memory string. For example, as shown in FIG. 1-3 and 7, in period 706, word line driver 308 of peripheral circuit 102 may be configured to apply the on voltage to the second DSG line (DSG1), and apply the off voltage to the first DSG line (DSG0).

Method 1300 proceeds to operation 1306, as illustrated in FIG. 13, in which in a third period of the program operation after the second period, an off voltage is applied to the first and second DSG lines coupled to the DSG transistors of the first and second memory strings, respectively, and a program voltage pulse is applied to the select word line. For example, as shown in FIG. 1-3 and 7, word line driver 308 of peripheral circuit 102 may be configured to, in period 710, apply the off voltages to the first and second DSG lines (DSG0 and DSG1), and apply the program voltage pulse to the select word line (Sel WL).

In some implementations, to apply the program voltage pulse to the select word line in the third period, the program voltage pulse on the select word line is ramped up to a first level, and the program voltage pulse on the select word line is maintained at the first level. For example, as shown in FIG. 1-3 and 7, word line driver 308 of peripheral circuit 102 may be configured to ramp up the program voltage pulse on the select word line to the program voltage level in period 710, and maintain the program voltage pulse at the program voltage level in period 710.

In some implementations, in the second period, a voltage at a second level lower than the first level is applied on the select word line. For example, as shown in FIG. 1-3 and 7, word line driver 308 of peripheral circuit 102 may be configured to apply the word line voltage at the intermediate voltage level lower than the program voltage level to the select word line in period 706.

In some implementations, in a fourth period of the program operation before the second period, the voltage on the select word line is ramped up to the second level. For example, as shown in FIG. 1-3 and 7, word line driver 308 of peripheral circuit 102 may be configured to ramp up the word line voltage on the select word line to the intermediate voltage level in period 704 before period 706.

Method 1300 proceeds to operation 1308, as illustrated in FIG. 13, in which a continuous pass voltage pulse is applied to an unselect word line during the second and third periods of the program operation. For example, as shown in FIG. 1-3 and 7, word line driver 308 of peripheral circuit 102 may be configured to apply the continuous pass voltage pulse to each unselect word line (Unsel WLs) during period 708 and period 710.

In some implementations, to apply the continuous pass voltage pulse to the unselect word line, the pass voltage pulse on the unselect word line is ramped up to a third level after the first period, and the pass voltage pulse on the unselect word line is maintained at the third level in the second and third periods. For example, as shown in FIG. 1-3 and 7, word line driver 308 of peripheral circuit 102 may be configured to ramp up the pass voltage pulse on the unselect word line to the pass voltage level in period 704 after period 702, and maintain the pass voltage pulse at the pass voltage level in period 708 and period 710.

Method 1300 proceeds to operation 1310, as illustrated in FIG. 13, in which a bit line voltage is applied to a bit line during the first period and the second period of the program operation. In some implementations, the bit line is coupled to the first memory cell and the second memory cell. In some implementations, the bit line voltage is at a ground level, such that the first and second memory strings are at the program state. For example, as shown in FIGS. 1-3 and 7, page buffer 304 of peripheral circuit 102 may be configured to apply the bit line voltage to the bit line (BL) during period 702 and period 706 to in period 702 load the first page of data (data0), and in period 706 load the second page of data (data1).

In some implementations, in a sixth period of the program operation after the second period and before the third period, an on voltage is applied to a third DSG line coupled to the DSG transistor of a third memory string of the memory strings, and the off voltages are applied to the first and second DSG lines coupled to the DSG transistors of the first and second memory strings, respective. For example, as shown in FIG. 1-3 and 7, in period 708 between period 706 and period 710, word line driver 308 of peripheral circuit 102 may be configured to apply the on voltage to the Nth DSG line (DSGN), and apply the off voltages to the first and second DSG lines (DSG0 and DSG1).

In some implementations, a channel potential of the first memory string is at a non-boosted level in the first, second, and third periods, a channel potential of the second memory string is at a non-boosted level in the second and third periods, and a channel potential of the third memory string is at a non-boosted level in the third period. For example, as shown in FIG. 7, the channel potentials of the NAND memory strings in the first memory string (Channel_pgm_set0) in the program state are at the non-boosted level in periods 702, 706, and 710, the channel potentials of the NAND memory strings in the second memory string in the program state (Channel_pgm_set1) are at the non-boosted level in periods 706 and 710, and the channel potentials of the NAND memory strings in the Nth memory string in the program state (Channel_pgm_setN) are at a non-boosted level in period 710.

In some implementations, in a fifth period of the program operation after the third period, the on voltages are applied to the first, second, and third DSG lines coupled to the DSG transistors of the first, second, and third memory strings, respectively, and the program voltage pulse on the select word line is discharged. For example, as shown in FIG. 1-3 and 7, in period 712, word line driver 308 of peripheral circuit 102 may be configured to apply the on voltages to the first, second, and Nth DSG lines (DSG0, DSG1, and DSGN), and discharge the program voltage pulse on the select word line (Sel WL).

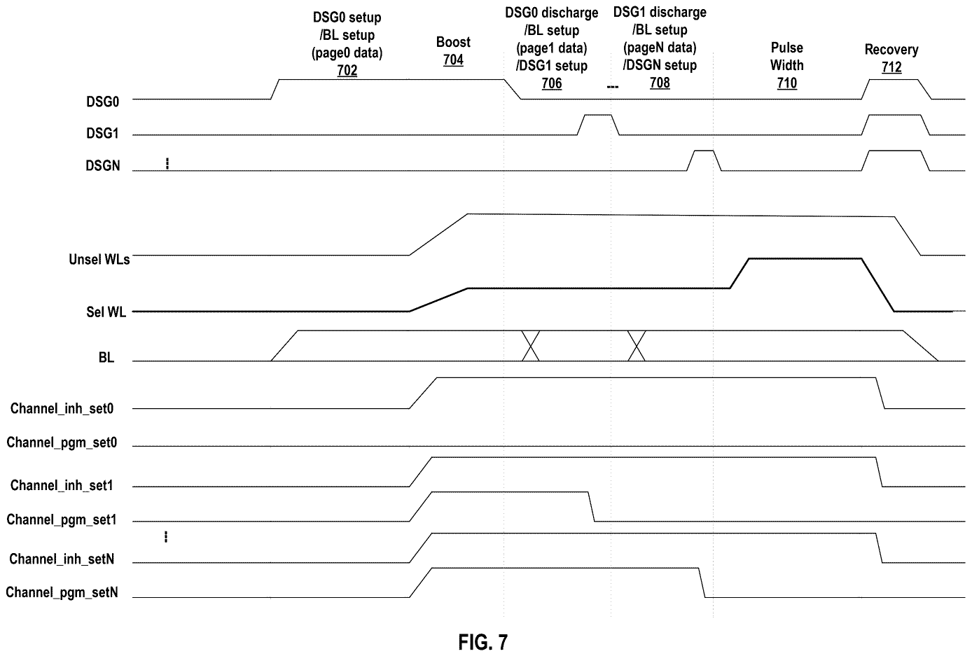

FIG. 8 illustrates interface timing diagrams of a program operation in an SLC mode, according to some aspects of the present disclosure. FIG. 8 will be described with respect to FIGS. 1-3, 4B, 6A, and 6B. Each of the first page of data (page0), second page of data (page1), and Nth page of data (pageN) can include a command (CMD) indicating the SLC mode, an address (ADDR) of the respective page corresponding to the respective select memory cell to be programmed, and user data (Din) of the respective page. As shown in FIG. 8, in the first DSG/BL setup period 602, control logic 312 of peripheral circuit 102 generates a ready signal, e.g., by setting the ready pin (RDY) to high/on and busy pin (ARDY) to low/off, such that the first page of data is received by page buffer 304 of peripheral circuit 102, and stored in a first data latch 408, according to some implementations. In other words, the first page of data for SLC programming the first set of memory strings can be loaded in the first DSG/BL setup period 602. As shown in FIG. 8, in the second DSG/BL setup period 608, control logic 312 of peripheral circuit 102 generates another ready signal, e.g., by setting the ready pin (RDY) to high/on again, such that the second page of data is received by page buffer 304 of peripheral circuit 102, and stored in a second data latch 408, according to some implementations. In other words, the second page of data for SLC programming the second set of memory strings can be pre-loaded in the second DSG/BL setup period 608 while programming the first set of memory strings to save programming time. Similarly, as shown in FIG. 8, in the last/Nth DSG/BL setup period 612, control logic 312 of peripheral circuit 102 generates still another ready signal, e.g., by setting the ready pin (RDY) to high/on again, such that the last/Nth page of data is received by page buffer 304 of peripheral circuit 102, and stored in the first data latch 408, according to some implementations. Accordingly, each page of data for SLC programming the perspective set of memory strings can be pre-loaded in the respective setup period while programming the previous set of memory strings to save programming time. In this case, only two data latches 408 may be needed to cache the data pages since each page of data will be programmed in the pulse width period immediately after the respective DSG/BL setup period and can be released for storing the next page of data afterward.

As described above, compared with the SLC programming schemes with respect to FIGS. 6A and 6B, the SLC programming scheme with respect to FIG. 7 can further reduce the programming time by reducing the number of pulse width periods to only one (i.e., having a single pulse width period instead of N pulse width periods as shown in FIGS. 6A and 6B). On the other hand, the reductions of the number of pulse width periods may make it difficult to pre-load the subsequent page of data according to the interface protocol described above in FIG. 8.

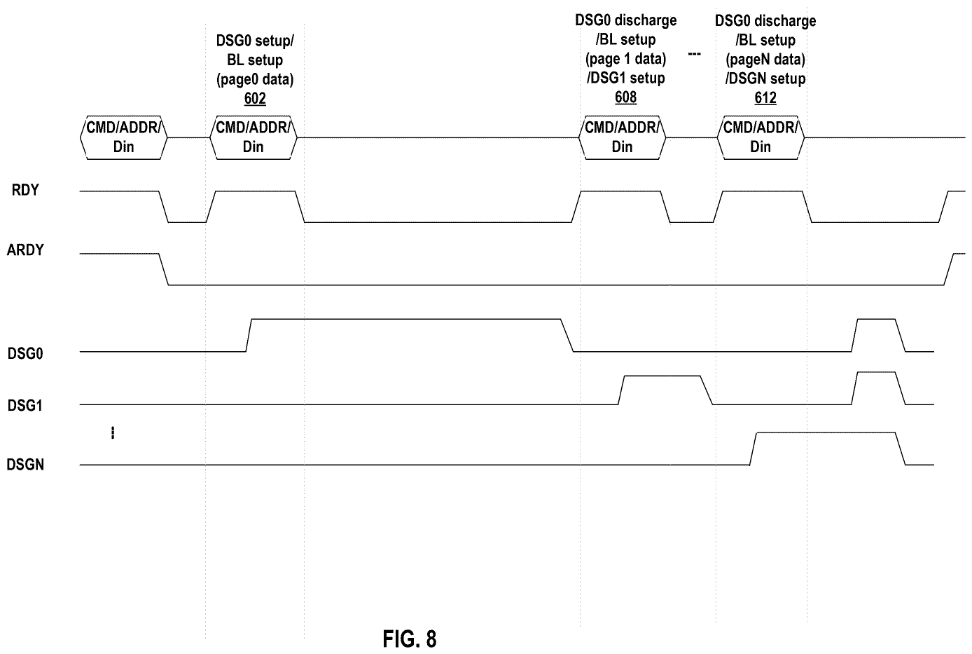

FIG. 9 illustrates interface timing diagrams of another program operation in an SLC mode, according to some aspects of the present disclosure. FIG. 9 will be described with respect to FIGS. 1-3, 4B, and 7. N pages of data for programming N sets of memory strings, respectively, in the SLC mode can be consecutively received by page buffer 304 of peripheral circuit 102, and stored in N data latches 408, respectively. As shown in the top row of FIG. 9, in some implementations, control logic 312 of peripheral circuit 102 generates a first ready signal, e.g., by setting the read/busy (R/B) pin to high/on, such that the first page of data is received by page buffer 304 of peripheral circuit 102 for programming the select memory cells of the first set of memory strings (Set0). The first page of data can include one or more commands (CMD) indicating the SLC mode, e.g., DAh and 80h, one or more addresses (ADDR) corresponding to the respective memory cell, e.g., C1 . . . R4 indicating Set0, and user data, e.g., D0 . . . Dn, in this order. As shown in the middle row of FIG. 9, in some implementations, control logic 312 of peripheral circuit 102 generates a second ready signal, e.g., by setting the read/busy (R/B) pin to high/on again, such that the second page of data is received by page buffer 304 of peripheral circuit 102 for programming the select memory cells of the second set of memory strings (Set1). The second page of data can include one or more commands (CMD) indicating the SLC mode, e.g., DAh and 80h, one or more addresses (ADDR) corresponding to the respective memory cell, e.g., C1 . . . R4 indicating Set1, and user data, e.g., D0 . . . Dn, in this order. As shown in the bottom row of FIG. 9, in some implementations, control logic 312 of peripheral circuit 102 generates an Nth ready signal, e.g., by setting the read/busy (R/B) pin to high/on again, such that the Nth page of data is received by page buffer 304 of peripheral circuit 102 for programming the select memory cells of the Nth set of memory strings (SetN). The Nth page of data can include one or more commands (CMD) indicating the SLC mode, e.g., DAh and 80h, one or more addresses (ADDR) corresponding to the respective memory cell, e.g., C1 . . . R4 indicating Set0, and user data, e.g., D0 . . . Dn, in this order.

After consecutively receiving and storing the N pages of data, the select memory cells in the N sets of memory strings can be programmed based on the N pages of data, respectively, in the SLC mode, in the single pulse width period (e.g., 710 in FIG. 7). Compared with the interface protocol with respect to FIG. 8, the interface protocol with respect to FIG. 9 can leave more time to pre-load the programming data. On the other hand, in this case, N data latches 408 may be needed to cache the N data pages since all the N pages of data will be programmed in a single pulse width period after pre-loading all the N data pages.

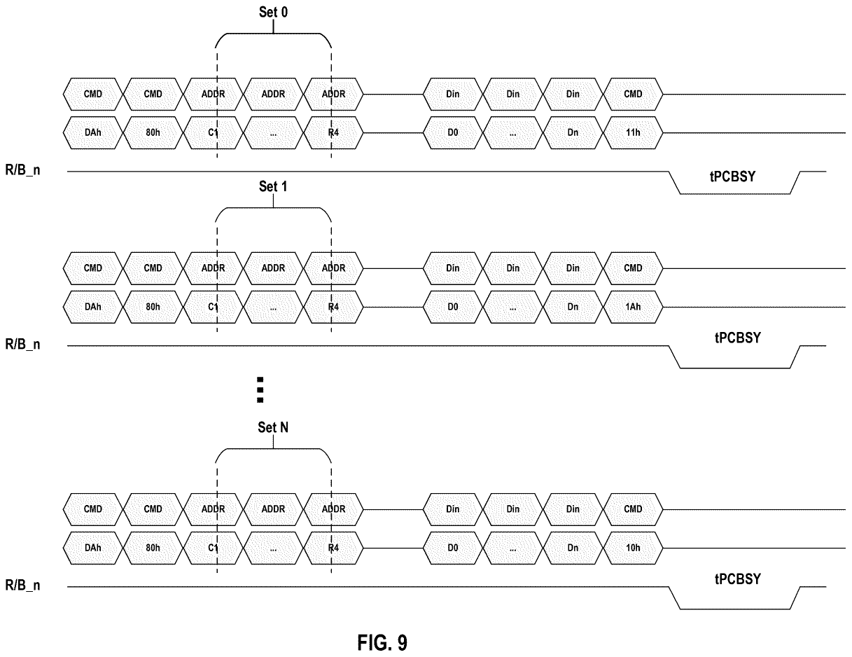

FIG. 10 illustrates interface timing diagrams of still another program operation in an SLC mode, according to some aspects of the present disclosure. The interface protocol with respect to FIG. 9 can be further expanded to accommodate multi-plane SLC programming. K groups of N pages of data for programming K planes each including N sets of memory strings, respectively, in the SLC mode can be consecutively received by page buffer 304 of peripheral circuit 102, respectively. As shown in the first row of FIG. 10, in some implementations, control logic 312 of peripheral circuit 102 generates a first ready signal, e.g., by setting the read/busy (R/B) pin to high/on, such that the first page of data of the first group is received by page buffer 304 of peripheral circuit 102 for programming the select memory cells of the first set of memory strings (Set0) in the first plane (PlaneA). The first page of data of the first group can include one or more commands (CMD) indicating the SLC mode, e.g., DAh and 80h, one or more addresses (ADDR) corresponding to the respective memory cell, e.g., C1 . . . R4 indicating Set0/PlaneA, and user data, e.g., D0 . . . Dn, in this order. Assuming K equals 2 (i.e., the memory device includes two planes), as shown in the second row of FIG. 10, in some implementations, control logic 312 of peripheral circuit 102 generates a second ready signal, e.g., by setting the read/busy (R/B) pin to high/on, such that the first page of data of the second group is received by page buffer 304 of peripheral circuit 102 for programming the select memory cells of the first set of memory strings (Set0) in the second plane (PlaneB). The first page of data of the second group can include one or more commands (CMD) indicating the SLC mode, e.g., DAh and 80h, one or more addresses (ADDR) corresponding to the respective memory cell, e.g., C1 . . . R4 indicating Set0/PlaneB, and user data, e.g., D0 . . . Dn, in this order. As shown in the third row of FIG. 10, in some implementations, control logic 312 of peripheral circuit 102 generates another ready signal, e.g., by setting the read/busy (R/B) pin to high/on, such that the Nth page of data of the first group is received by page buffer 304 of peripheral circuit 102 for programming the select memory cells of the Nth set of memory strings (SetN) in the first plane (PlaneA). The Nth page of data of the first group can include one or more commands (CMD) indicating the SLC mode, e.g., DAh and 80h, one or more addresses (ADDR) corresponding to the respective memory cell, e.g., C1 . . . R4 indicating SetN/PlaneA, and user data, e.g., D0 . . . Dn, in this order. As shown in the fourth row of FIG. 10, in some implementations, control logic 312 of peripheral circuit 102 generates still another ready signal, e.g., by setting the read/busy (R/B) pin to high/on, such that the Nth page of data of the second group is received by page buffer 304 of peripheral circuit 102 for programming the select memory cells of the Nth set of memory strings (SetN) in the second plane (PlaneB). The Nth page of data of the second group can include one or more commands (CMD) indicating the SLC mode, e.g., DAh and 80h, one or more addresses (ADDR) corresponding to the respective memory cell, e.g., C1 . . . R4 indicating SetN/PlaneB, and user data, e.g., D0 . . . Dn, in this order.

After consecutively receiving and storing the K groups of N pages of data, for each o the K planes, the select memory cells in the N sets of memory strings in the respective plane can be programmed based on the N pages of data, respectively, in the SLC mode, in the single pulse width period (e.g., 710 in FIG. 7).

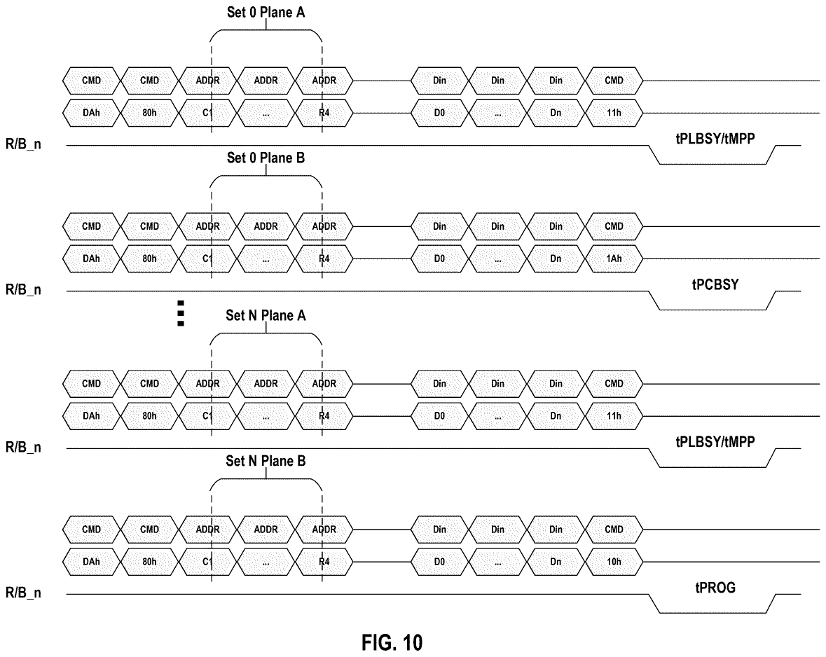

FIG. 11 illustrates interface timing diagrams of yet another program operation in an SLC mode, according to some aspects of the present disclosure. As described above, N data latches 408 may be needed for the interface protocol with respect to FIG. 9. As shown in FIG. 11, in some implementations, after all the DSG/BL setup periods (e.g., 702, 706, and 708 in FIG. 7), since all the N pages of data have been loaded to the select memory cells of the N sets of memory strings (Set0-SetN) coupled to the select word line (WL0) for programming in the SLC mode, all N data latches can be released. Thus, during the following pulse width period (e.g., 710 in FIG. 7), while programming the select memory cells coupled to the select word line (WL0) based on the loaded N pages of data, the next N pages of data for programming the select memory cells of the N sets of memory strings (Set0-SetN) coupled to the next select word line (WL1) can be pre-loaded/cached to the N data latches to save the programming time.

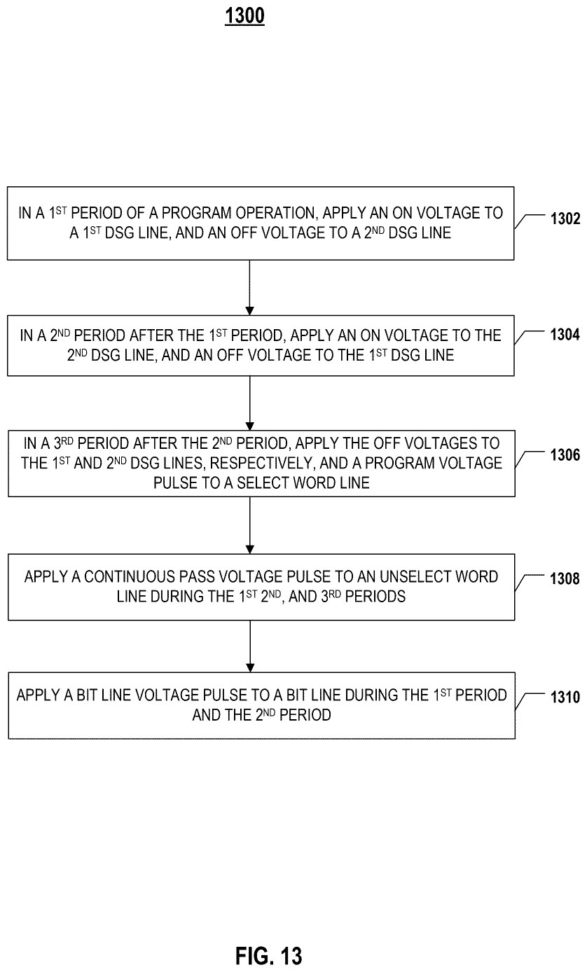

FIG. 14 illustrates a flowchart of still another method 1400 for programming a memory device, according to some aspects of the present disclosure. The memory device may be any suitable memory device disclosed herein, such as memory device 100. Method 1400 may be implemented by peripheral circuit 102, such as row decoder/word line driver 308, page buffer/sense amplifier 304, and control logic 312. It is understood that the operations shown in method 1400 may not be exhaustive and that other operations can be performed as well before, after, or between any of the illustrated operations. Further, some of the operations may be performed simultaneously, or in a different order than shown in FIG. 14.

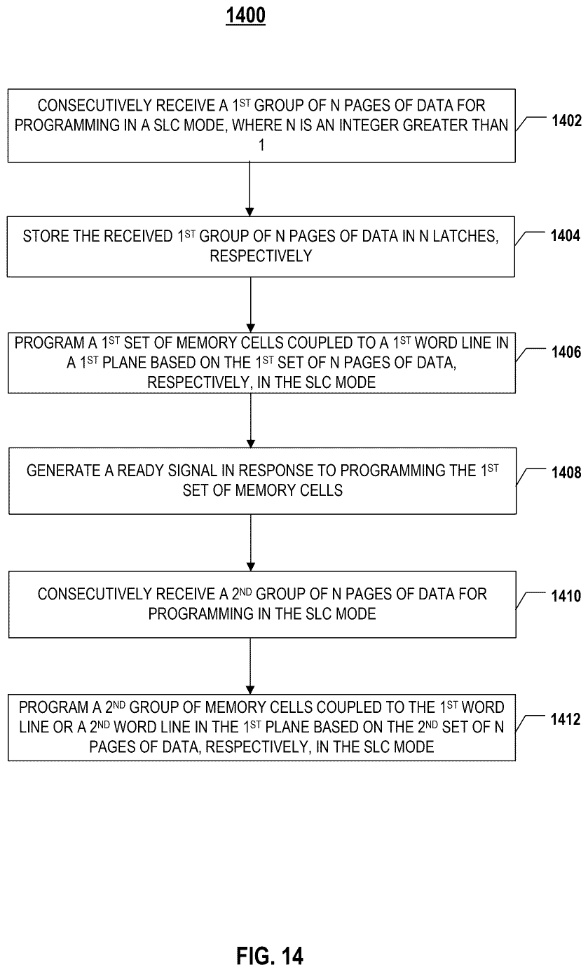

Referring to FIG. 14, method 1400 starts at operation 1402, in which a first group o N pages of data for programming in an SLC mode are consecutively received, where N is an integer greater than 1. In some implementations, for each page of the N pages of data, a command indicating the SLC mode is received, an address of the respective page corresponding to the respective memory cell is received, and user data of the respective page is received. For example, as shown in FIG. 1-3, 4B, 7, and 9-11, page buffer 304 of peripheral circuit 102 may be configured to consecutively receive a first group of N pages of data for programming in an SLC mode, for example, from a memory controller (e.g., memory controller 1506 in FIG. 15).

Method 1400 proceeds to operation 1404, as illustrated in FIG. 14, in which the received first group of N pages of data are stored in N latches, respectively, before programming a first group of memory cells. For example, as shown in FIG. 1-3, 4B, 7, and 9-11, N data latches 408 of page buffer 304 of peripheral circuit 102 may be configured to store the received first group of N pages of data, respectively, before SLC programming.

Method 1400 proceeds to operation 1406, as illustrated in FIG. 14, in which a first group of memory cells coupled to a first word line in a first plane are programmed based on the first group of N pages of data, respectively, in the SLC mode. In some implementations, the first plane includes multiple blocks, each of the blocks includes N sets of memory strings, and each of the N sets includes M memory strings, where M is an integer greater than 1. In some implementations, the first word line is coupled to MN memory cells. In some implementations, N equals 4 or 6. For example, as shown in FIG. 1-3, 4B, 7, and 9-11, in period 712, peripheral circuit 102 may be configured to program the select memory cells in the N sets of memory strings based on the first group of N pages of data, respectively, in the SLC mode.

Method 1400 proceeds to operation 1408, as illustrated in FIG. 14, in which a ready signal is generated in response to programming the first group of memory cells For example, as shown in FIG. 1-3, 4B, and 9-11, control logic 312 of peripheral circuit 102 may be configured to generate a ready signal (e.g., by setting RDY or R/B_n to high/on) in response to programming the select memory cells coupled to the select word line based on the first group of N pages of data.

In some implementations, the ready signal is generated during the programming of the first group of memory cells. For example, as shown in FIG. 11, the next N pages of data for programming the next select word line (WL1) may be pre-loaded/cached during programming the select memory cells coupled to the select word line (WL0). In some implementations, the ready signal is generated after programming the first group of memory cells. That is, the next N pages of data for programming the next select word line (WL1) may not be pre-loaded/cached, but instead, loaded after programming the select memory cells coupled to the select word line (WL0).

Method 1400 proceeds to operation 1410, as illustrated in FIG. 14, in which a second group of N pages of data for programming in the SLC mode are consecutively received. Method 1400 proceeds to operation 1412, as illustrated in FIG. 14, in which a second group of memory cells coupled to a second word line or the first word line in the first plane are programmed based on the second group of N pages of data, respectively, in the SLC mode.

In some implementations, the second group of memory cells coupled to the second word line in the first plane are programmed based on the second group of N pages of data, respectively, in the SLC mode. For example, the first group of memory cells may include all the select memory cells coupled to the first word line such that all the select memory cells coupled to the first word line have been programmed in operation 1406. In other words, all the pages of data needed to program all the select memory cells coupled to the first word line may be consecutively received in a single batch before programming the select memory cells programmed in operation 1406.

In some implementations, the second group of memory cells coupled to the first word line in the first plane are programmed based on the second group of N pages of data, respectively, in the SLC mode. For example, the first group of memory cells may include some of the select memory cells coupled to the first word line, and the second group of memory cells may include some of the select memory cells coupled to the first word line as well, such that the first and second groups of memory cells may be programmed together based on the first and second groups of 2N pages of data in a single programming operation (i.e., operations 1406 and 1410 are combined into a single programming operation). In other words, all the pages of data needed to program all the select memory cells coupled to the first word line may be received in two or more separate batches before programming the select memory cells.

In some implementations, K groups of N pages of data for programming in the SLC mode are consecutively received, where K is an integer greater than 1, and for each of K planes of the memory device, a group of memory cells coupled to a same word line are programmed based on the respective group of N pages of data, respectively, in the SLC mode. For example, as shown in FIG. 10 where K equals 2, two groups of N pages of data for programming in the SLC mode are consecutively received, and for each of the two planes (PlaneA and PlaneB), a group of memory cells coupled to a same word line are programmed based on the respective group of N pages of data, respectively, in the SLC mode.

FIG. 15 illustrates a block diagram of a system 1500 having a memory device, according to some aspects of the present disclosure. System 1500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 15, system 1500 can include a host 1508 and a memory system 1502 having one or more memory devices 100 (shown in FIG. 1) and a memory controller 1506. Host 1508 can be a processor of an electronic device, such as a central processing unit (CPU), or a system-on-chip (SoC), such as an application processor (AP). Host 1508 can be configured to send or receive data to or from memory devices 100.

Memory device 100 can be any memory device disclosed in the present disclosure. Memory controller 1506 is coupled to memory device 100 and host 1508 and is configured to control memory device 100, according to some implementations. Memory controller 1506 can manage the data stored in memory device 100 and communicate with host 1508. In some implementations, memory controller 1506 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1506 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1506 can be configured to control operations of memory device 100, such as read, erase, and program operations. Memory controller 1506 can also be configured to manage various functions with respect to the data stored or to be stored in memory device 100 including, but not limited to bad-block management, garbage collection, logical-to-physical address conversion, wear leveling, etc. In some implementations, memory controller 1506 is further configured to process error correction codes (ECCs) with respect to the data read from or written to memory device 100. Any other suitable functions may be performed by memory controller 1506 as well, for example, formatting memory device 100. Memory controller 1506 can communicate with an external device (e.g., host 1508) according to a particular communication protocol. For example, memory controller 1506 may communicate with the external device through at least one of various interface protocols, such as a USB protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Consistent with the scope of the present disclosure, in some implementations, memory device 100 is configured to consecutively receive a first group of N pages of data for programming in an SLC mode from memory controller 1506, where N is an integer greater than 1, and program a first group of memory cells coupled to a first word line based on the first group of N pages of data, respectively, in the SLC mode. In some implementations, memory device 100 is also configured to generate a busy signal when programming the first group of memory cells. In some implementations, memory device 100 is further configured to generate a second ready signal in response to programming the first group of memory cells, and consecutively receiving a second group of N pages of data for programming in the SLC mode from memory controller 1506.

Consistent with the scope of the present disclosure, in some implementations, memory controller 1506 is configured to in response to receiving a first ready signal from memory device 100, consecutively transmit a first group of N pages of data to memory device 100, and consecutively transmit the first group of N pages of data to memory device 100 until receiving the busy signal from memory device 100. In some implementations, memory controller 1506 is further configured to in response to receiving the second ready signal from memory device 100, consecutively transmit the second group of N pages of data to memory device 100.

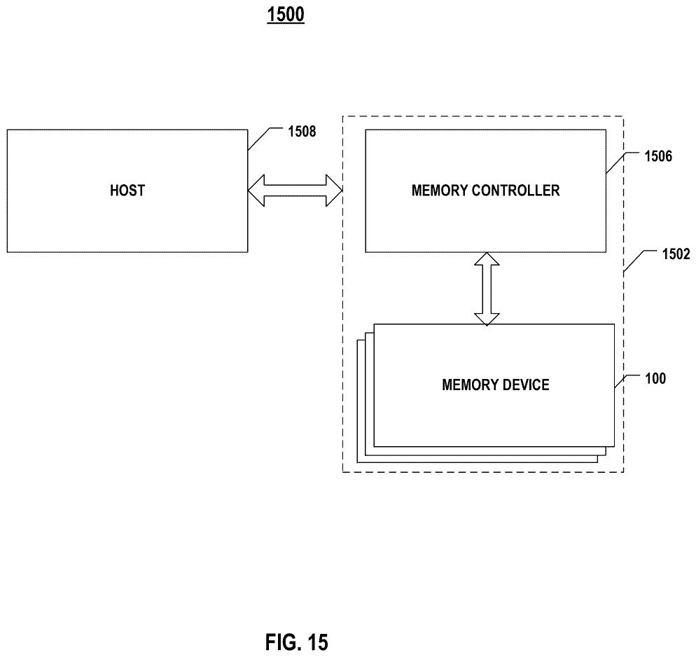

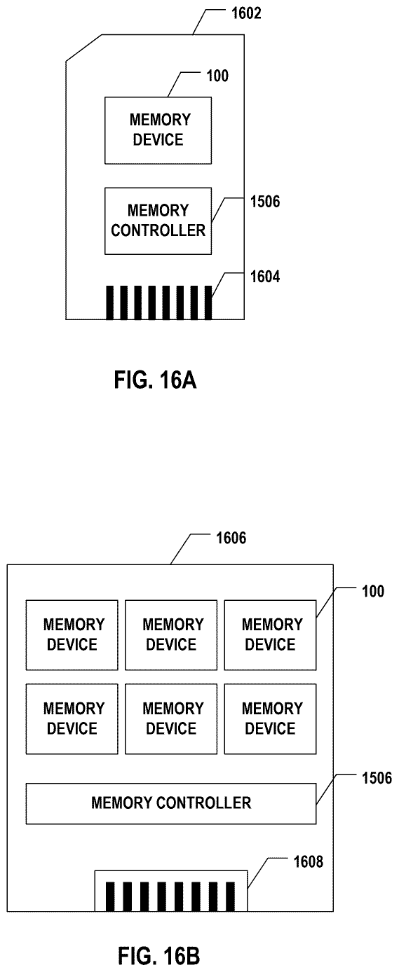

Memory controller 1506 and one or more memory devices 100 can be integrated into various types of storage devices, for example, being included in the same package, such as a universal Flash storage (UFS) package or an eMMC package. That is, memory system 1502 can be implemented and packaged into different types of end electronic products. In one example as shown in FIG. 16A, memory controller 1506 and a single memory device 100 may be integrated into a memory card 1602. Memory card 1602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1602 can further include a memory card connector 1604 coupling memory card 1602 with a host (e.g., host 1508 in FIG. 15). In another example as shown in FIG. 16B, memory controller 1506 and multiple memory devices 100 may be integrated into an SSD 1606. SSD 1606 can further include an SSD connector 1608 coupling SSD 1606 with a host (e.g., host 1508 in FIG. 15). In some implementations, the storage capacity and/or the operation speed of SSD 1606 is greater than those of memory card 1602.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

Although specific configurations and arrangements are discussed, it should be understood that this is done for illustrative purposes only. As such, other configurations and arrangements can be used without departing from the scope of the present disclosure. Also, the subject matter as described in the present disclosure can also be used in a variety of other applications. Functional and structural features as described in the present disclosures can be combined, adjusted, modified, and rearranged with one another and in ways that are consistent with the scope of the present disclosure.

What is claimed is:

1. A memory device, comprising:
memory strings each comprising a drain select gate (DSG) transistor and memory cells;
word lines and DSG lines coupled to the memory strings; and
a peripheral circuit coupled to the memory strings through the word lines and the DSG lines and configured to, in a program operation, program a first memory cell of the memory cells in a first memory string of the memory strings, and a second memory cell of the memory cells in a second memory string of the memory strings,
wherein the first memory cell and the second memory cell are coupled to a same select word line of the word lines; and
the peripheral circuit comprises a word line driver configured to:
in a first period of the program operation, apply an on voltage to a first DSG line of the DSG lines coupled to the DSG transistor of the first memory string, and apply an off voltage to a second DSG line coupled to a second DSG line of the DSG lines coupled to the DSG transistor of the second memory string;
in a second period of the program operation after the first period, apply an on voltage to the second DSG line coupled to the DSG transistor of the second memory string, and apply an off voltage to the first DSG line coupled to the DSG transistor of the first memory string; and
in a third period of the program operation after the second period, apply an off voltage to the first and second DSG lines coupled to the DSG transistors of the first and second memory strings, respectively, and apply a program voltage pulse to the select word line.

2. The memory device of claim 1, wherein to apply the program voltage pulse to the select word line, the word line driver is configured to, in the third period:
ramp up the program voltage pulse on the select word line to a first level; and
maintain the program voltage pulse on the select word line at the first level.

3. The memory device of claim 2, wherein the word line driver is configured to in the second period, apply a voltage at a second level lower than the first level on the select word line.

4. The memory device of claim 3, wherein the word line driver is configured to in a fourth period of the program operation before the second period, ramp up the voltage on the select word line to the second level.

5. The memory device of claim 1, wherein the word line driver is further configured t apply a continuous pass voltage pulse to an unselect word line of the word lines during the second and third periods of the program operation.

6. The memory device of claim 5, wherein to apply the continuous pass voltage pulse to the unselect word line, the word line driver is configured to:
ramp up the pass voltage pulse on the unselect word line to a third level after the first period; and
maintain the pass voltage pulse on the unselect word line at the third level in the second and third periods.

7. The memory device of claim 1, further comprising a bit line coupled to the first memory cell and the second memory cell,
wherein the peripheral circuit further comprises a page buffer coupled to the bit line and configured to apply a bit line voltage to the bit line during the first period and the second period.

8. The memory device of claim 7, wherein the bit line voltage is at a ground level.

9. The memory device of claim 1, wherein the word line driver is further configured to, in a fifth period of the program operation after the third period:
apply the on voltages to the first and second DSG lines coupled to the DSG transistors of the first and second memory strings, respectively; and
discharge the program voltage pulse on the select word line.

10. The memory device of claim 1, wherein
the peripheral circuit is further configured to, in the program operation, program a third memory cell of the memory cells in a third memory string of the memory strings, the third memory cell being coupled to the select word line; and
the word line driver is further configured to in a sixth period of the program operation after the second period and before the third period, apply an on voltage to a third DSG line of the DSG lines coupled to the DSG transistor of the third memory string, and apply the off voltages to the first and second DSG lines coupled to the DSG transistors of the first and second memory strings, respectively.

11. The memory device of claim 1, wherein the program operation is performed for single-level cells (SLCs).

12. The memory device of claim 1, wherein
a channel potential of the first memory string is at a non-boosted level in the first, second, and third periods;
a channel potential of the second memory string is at a non-boosted level in the second and third periods; and
a channel potential of the third memory string is at a non-boosted level in the third period.

13. A method for operating a memory device, the memory device comprising memory strings each comprising a drain select gate (DSG) transistor and memory cells, the method comprising:
in a first period of a program operation, applying an on voltage to a first DSG line coupled to the DSG transistor of a first memory string of the memory strings, and an off voltage to a second DSG line coupled to the DSG transistor of a second memory string of the memory strings;
in a second period of the program operation after the first period, applying an on voltage to the second DSG line coupled to the DSG transistor of the second memory string, and an off voltage to the first DSG line coupled to the DSG transistor of the first memory string; and
in a third period of the program operation after the second period, applying the off voltages to the first and second DSG lines coupled to the DSG transistors of the first and second memory strings, respectively, and applying a program voltage pulse to a select word line, wherein the select word line is coupled to a first memory cell of the memory cells in the first memory string and a second memory cell of the memory cells in the second memory string.

14. The method of claim 13, wherein applying the program voltage pulse to the select word line comprises, in the third period:
ramping up the program voltage pulse on the select word line to a first level; and
maintaining the program voltage pulse on the select word line at the first level.

15. The method of claim 14, further comprising in the second period, applying a voltage at a second level lower than the first level on the select word line.

16. The method of claim 13, further comprising applying a continuous pass voltage pulse to an unselect word line during the second and third periods of the program operation.

17. The method of claim 13, further comprising applying a bit line voltage to a bit line during the first period and the second period, wherein the bit line is coupled to the first memory cell and the second memory cell.

18. The method of claim 13, further comprising in a fifth period of the program operation after the third period:
applying the on voltages to the first and second DSG lines coupled to the DSG transistors of the first and second memory strings, respectively; and
discharging the program voltage pulse on the select word line.

19. The method of claim 13, further comprising in a sixth period of the program operation after the second period and before the third period, applying an on voltage to a third DSG line coupled to the DSG transistor of a third memory string of the memory strings, and the off voltages to the first and second DSG lines coupled to the DSG transistors of the first and second memory strings, respectively.

20. A system, comprising:
a memory device configured to store data, the memory device comprising memory strings each comprising a drain select gate (DSG) transistor and memory cells;
word lines and DSG lines coupled to the memory strings; and
a peripheral circuit coupled to the memory strings through the word lines and the DSG lines and configured to, in a program operation, program a first memory cell of the memory cells in a first memory string of the memory strings, and a second memory cell of the memory cells in a second memory string of the memory strings,
wherein the first memory cell and the second memory cell are coupled to a same select word line of the word lines; and
the peripheral circuit comprises a word line driver configured to:
in a first period of the program operation, apply an on voltage to a first DSG line of the DSG lines coupled to the DSG transistor of the first memory string, and apply an off voltage to a second DSG line of the DSG lines coupled to the DSG transistor of the second memory string;
in a second period of the program operation after the first period, apply an on voltage to the second DSG line coupled to the DSG transistor of the second memory string, and apply an off voltage to the first DSG line coupled to the DSG transistor of the first memory string; and
in a third period of the program operation after the second period, apply the off voltages to the first and second DSG lines coupled to the DSG transistors of the first and second memory strings, respectively, and apply a program voltage pulse to the select word line; and
a memory controller coupled to the memory device and configured to control the memory device.
